(19) United States
(12) Patent Application Publication
(10) Pub. No.: US 2026/0142657 A1
(43) Pub. Date: May 21, 2026

(54) DRIVING CIRCUIT FOR SLEW RATE CONTROL AND GATE DRIVER INCLUDING THE SAME

(71) Applicant: LX SEMICON CO., LTD., Daejeon (KR)

(72) Inventors: Jong Hyun YOON, Daejeon (KR); Won June HWANG, Daejeon (KR); Cheol Ho LEE, Daejeon (KR); Won Suk JANG, Daejeon (KR)

(73) Assignee: LX SEMICON CO., LTD., Daejeon (KR)

(21) Appl. No.: 19/389,629

(22) Filed: Nov. 14, 2025

(30) Foreign Application Priority Data
Nov. 15, 2024 (KR) 10-2024-0162860

(51) Int. Cl. H03K 17/16

(52) U.S. Cl. CPC H03K 17/165

(57) ABSTRACT

A gate driver for slew rate control includes a buffer controller that switches and outputs a power supply voltage by a high or low level control signal; a buffer unit that delays and outputs the voltage output by the buffer controller; an output switch unit that is turned on or off according to a voltage level applied through the buffer unit and outputs a driving voltage by including an output transistor, wherein an input terminal of the buffer unit is connected to a gate terminal of the output transistor; a capacitor electrically connected between the input terminal of the buffer unit and a drain terminal of the output transistor; and a current source that is connected to the power supply voltage terminal and generates a current that is charged in the capacitor, wherein the capacitor adjusts a slope of a gate voltage of the output transistor during a rising or falling transition, and the output transistor may adjust a slope of the driving voltage output to the drain terminal during a falling or rising transition by the capacity of the capacitor.

### CROSS-REFERENCE TO RELATED APPLICATION

This application claims the priority of Korean Patent Application No. 10-2024-0162860, filed on Nov. 15, 2024, which is hereby incorporated by reference in its entirety.

### BACKGROUND

### Field of the Disclosure

The present disclosure relates to a driving circuit for slew rate control and a gate driver including the driving circuit.

### Description of the Background

A MOSFET includes an N-channel MOSFET and a P-channel MOSFET, and the gate, drain, and source are insulated by a gate oxide film. The parasitic capacitance between the gate and source of the MOSFET and the parasitic capacitance between the gate and drain are determined by the capacitance of the gate oxide film. In particular, the parasitic capacitance between the gate and drain of a MOSFET forms a feedback path from the drain output to the gate input. This parasitic capacitance is amplified according to the voltage gain, imposing a capacitance on the input terminal that is much larger than the small-signal capacitance.

The rate at which the output signal at the drain of a MOSFET follows the input signal at the gate is defined as the slew rate. If the slew rate is too high, the peak current increases, which may cause electromagnetic interference (EMI) noise. Therefore, a circuit and gate driver capable of controlling the slew rate to prevent EMI are required.

### SUMMARY

The present disclosure provides a driving circuit capable of minimizing the influence of an output transistor by controlling a slew rate of an output voltage, a gate driver including the driving circuit, and an electronic device including the gate driver.

A gate driver for slew rate control according to an aspect of the present disclosure may include: a buffer control unit configured to switch and output a power supply voltage in response to a control signal having a high or low level; a buffer unit configured to delay and output a voltage output from the buffer control unit; an output switch unit including an output transistor, wherein a gate terminal of the output transistor is connected to an input terminal of the buffer unit, and the output transistor is turned on or off in accordance with a voltage level applied through the buffer unit to output a driving voltage; a capacitor electrically coupled between the input terminal of the buffer unit and a drain terminal of the output transistor; and a current source coupled to a power supply voltage terminal and configured to generate a charging current for charging the capacitor, wherein the capacitor adjusts a slope during a rising or falling transition of a gate voltage of the output transistor, and the output transistor adjusts a slope during a falling or rising transition of the driving voltage output to the drain terminal according to a capacitance of the capacitor.

According to an aspect of the present disclosure, the buffer control unit may include a first switch configured to be selectively turned on or off to connect or disconnect the current source in response to an inverted version of the control signal; and a second switch configured to be selectively turned on or off to connect or disconnect an output terminal of the first switch in response to the control signal, the buffer unit may include a buffer coupled to a first node between the output terminal of the first switch and an input terminal of the second switch, one terminal of the capacitor being coupled to the first node and the other terminal of the capacitor being coupled to the drain terminal of the output transistor, and a gate terminal of the output transistor being coupled to an output terminal of the buffer.

According to an aspect of the present disclosure, the buffer control unit may include first to third switches each configured to selectively connect input and output terminals in response to the control signal; and a first transistor having a drain terminal and a gate terminal coupled to the current source and a source terminal coupled to an input terminal of the first switch, the third switch may be coupled to a drain terminal of the first transistor in response to an inverted version of the control signal, the buffer unit may include a buffer having an input terminal coupled to an input terminal of the second switch and an output terminal of the third switch, and an output terminal coupled to a gate terminal of the output transistor, and one terminal of the capacitor may be coupled to the first node at which the drain terminal of the first transistor and the current source are coupled, and the other terminal of the capacitor may be coupled to the drain terminal of the output transistor.

According to an aspect of the present disclosure, the buffer control unit may include first to fifth switches each configured to selectively connect input and output terminals in response to the control signal; and a first transistor having a drain terminal and a gate terminal coupled to output terminals of fourth and fifth switches and a source terminal coupled to an input terminal of the first switch, the third switch may be coupled to a drain terminal of the first transistor in response to an inverted version of the control signal, the fourth switch may be configured to selectively connect a first current source coupled to the power supply voltage and the drain terminal of the first transistor in response to the control signal, and the fifth switch may be configured to selectively connect a second current source coupled to the power supply voltage and the drain terminal of the first transistor in response to an inverted version of the control signal, the buffer unit may include a buffer having an input terminal coupled to an input terminal of the second switch and an output terminal of the third switch, and an output terminal coupled to a gate terminal of the output transistor, one terminal of the capacitor being coupled to the first node at which the drain terminal of the first transistor and output terminals of the fourth and fifth switches connected to the first and second current sources are coupled, and the other terminal of the capacitor being coupled to the drain terminal of the output transistor.

According to an aspect of the present disclosure, the buffer control unit may include a first transistor having a gate terminal coupled to a control signal line, the buffer unit including: a second transistor having a gate terminal coupled to the control signal line; a third transistor having a drain terminal and a gate terminal coupled to the current source and a source terminal coupled to a drain terminal of the first transistor; and a fourth transistor having a drain terminal coupled to the power supply voltage, a gate terminal coupled to a gate terminal of the third transistor, and a source terminal coupled to the drain terminal of the first transistor, one terminal of the capacitor being coupled to the first node at which the drain terminal of the first transistor and a source terminal of the third transistor are connected, and the other terminal of the capacitor being coupled to the drain terminal of the output transistor.

According to an aspect of the present disclosure, the buffer control unit may include a first transistor having a gate terminal coupled to a control signal line; a third transistor having a gate terminal coupled to the control signal line and a source terminal coupled to the power supply voltage; and a fifth transistor having a source terminal coupled to a drain terminal of the first transistor and a drain terminal and a gate terminal coupled to the first node to which the buffer unit is coupled, the buffer unit may include: a second transistor having a gate terminal coupled to the control signal line and a drain terminal coupled to a gate terminal of the output transistor; a fourth transistor having a drain terminal and a gate terminal coupled to the current source and a source terminal coupled to the first node; and a sixth transistor having a gate terminal coupled to the current source, a drain terminal coupled to a drain terminal of the third transistor, and a source terminal coupled to both the drain terminal of the second transistor and the gate terminal of the output transistor, one terminal of the capacitor being coupled to the first node, and the other terminal of the capacitor being coupled to the drain terminal of the output transistor.

According to an aspect of the present disclosure, the buffer control unit may include a first transistor having a gate terminal coupled to a control signal line; a third transistor having a gate terminal coupled to the control signal line and a source terminal coupled to the power supply voltage; and a fifth transistor having a source terminal coupled to a drain terminal of the first transistor and a drain terminal and a gate terminal coupled to the buffer unit, the buffer unit may include: a second transistor having a gate terminal coupled to the control signal line and a drain terminal coupled to a gate terminal of the output transistor; a fourth transistor having a drain terminal and a gate terminal coupled to the first node to which the current source is coupled and a source terminal coupled to a drain terminal of the fifth transistor; and a sixth transistor having a source terminal coupled to both the drain terminal of the second transistor and the gate terminal of the output transistor, one terminal of the capacitor being coupled to the first node at which the drain terminal of the fourth transistor and the current source are coupled, and the other terminal of the capacitor being coupled to the drain terminal of the output transistor.

According to an aspect of the present disclosure, the buffer control unit may include a first transistor having a gate terminal coupled to a control signal line; an inverter configured to invert the control signal; a third transistor having a source terminal coupled to a first current source coupled to the power supply voltage and a gate terminal coupled to the inverter; a fourth transistor having a source terminal coupled to a second current source coupled to the power supply voltage and a gate terminal coupled to the control signal line; a fifth transistor having a source terminal coupled to the power supply voltage and a gate terminal coupled to the control signal line; and a seventh transistor having a drain terminal and a gate terminal coupled to the buffer unit and a source terminal coupled to a drain terminal of the first transistor, the buffer unit may include: a second transistor having a gate terminal coupled to the control signal line and a drain terminal coupled to a gate terminal of the output transistor; a sixth transistor having a drain terminal and a gate terminal coupled to the first node at which drain terminals of the third and fourth transistors are coupled; and an eighth transistor having a drain terminal coupled to a drain terminal of the fifth transistor, a gate terminal coupled to the first node, and a source terminal coupled to the gate terminal of the output transistor, one terminal of the capacitor being coupled to the first node at which the drain terminals of the fourth and sixth transistors may be coupled, and the other terminal of the capacitor being coupled to the drain terminal of the output transistor.

According to an aspect of the present disclosure, a slope compensation circuit connected between the buffer and the output transistor may be included, the slope compensation circuit including: a comparator configured to compare a voltage level of the gate terminal of the output transistor coupled to a negative input terminal with a high level of a positive input terminal and to output a comparison result; a logic OR circuit configured to logically combine the output of the comparator and the control signal; and a tenth transistor having a gate terminal coupled to an output terminal of the logic OR circuit, a source terminal coupled to the power supply voltage, and a drain terminal coupled to the gate terminal of the output transistor.

According to an aspect of the present disclosure, an inductor may be included and having one terminal to which an external power supply is applied and another terminal coupled to both the drain terminal of the output transistor and the other terminal of the capacitor.

According to an aspect of the present disclosure, when the control signal transitions from a high level to a low level, a voltage of a gate terminal of the output transistor may rise with a slope of a first current applied through the first node charged by the capacitor, and a driving voltage may decrease with a slope of the first current charged in the capacitor.

According to an aspect of the present disclosure, the output transistor may include an NMOS transistor.

According to an aspect of the present disclosure, the capacitor may have a capacitance greater than a parasitic capacitance between a gate terminal and a drain terminal of the output transistor.

According to an aspect of the present disclosure, the gate driver may include a plurality of gate drivers coupled to a control signal line.

According to at least one of the various aspects of the present disclosure, by adding a capacitor between the gate terminal and the drain terminal of the output transistor, the influence of the slew rate on the output of the output transistor may be minimized.

According to at least one of the various aspects of the present disclosure, by connecting a buffer to the gate terminal of the output transistor, the influence of parasitic capacitance on the driving voltage of the output transistor may be minimized.

According to at least one of the various aspects of the present disclosure, by arranging a buffer at the gate terminal of the output transistor, the deviation between driving voltages due to the Miller plateau voltage of the output transistor may be minimized.

According to at least one of the various aspects of the present disclosure, there is an advantage in that the reliability of a driving circuit, a gate driver including the driving circuit, or a power management circuit (PMIC) may be improved by reducing or eliminating electromagnetic interference (EMI) based on slew rate control.

It is to be understood that both the foregoing general description and the following detailed description are exemplary and explanatory and are intended to provide further explanation of the disclosure as claimed.

### BRIEF DESCRIPTION OF THE DRAWINGS

The above and other features and advantages of the present disclosure will become more apparent to those of ordinary skill in the art by describing exemplary aspects thereof in detail with reference to the accompanying drawings, in which:

FIG. 1 is a block diagram of a driving circuit and a gate driver for controlling slew rate according to an aspect of the present disclosure;

FIG. 2 is a circuit diagram of a driving circuit and a gate driver for controlling slew rate according to a first aspect of the present disclosure;

FIG. 3A is a waveform diagram of each component of FIG. 2;

FIG. 3B is an output waveform diagram of a gate driver according to a comparative example;

FIG. 4 is a circuit diagram of a circuit and a gate driver for controlling a slew rate according to a second aspect of the present disclosure;

FIG. 5 is a waveform diagram of each component of FIG. 4;

FIG. 6 is a circuit diagram of a circuit and a gate driver for controlling a slew rate according to a third aspect of the present disclosure;

FIG. 7 is a waveform diagram of each component of FIG. 6;

FIG. 8 is a circuit diagram of a circuit and a gate driver for controlling a slew rate according to a fourth aspect of the present disclosure;

FIG. 9 is a waveform diagram of each component of FIG. 8;

FIG. 10 is a circuit diagram of a circuit and a gate driver for controlling a slew rate according to a fifth aspect of the present disclosure;

FIG. 11 is a waveform diagram of each part of FIG. 10;

FIG. 12 is a circuit diagram of a circuit and a gate driver for controlling a slew rate according to a sixth aspect of the present disclosure;

FIG. 13 is a waveform diagram of each part of FIG. 12;

FIG. 14 is a circuit diagram of a circuit and a gate driver for controlling a slew rate according to a seventh aspect of the present disclosure;

FIG. 15 is a waveform diagram of each part of FIG. 14;

FIG. 16 is a circuit diagram of a gate driver including a circuit for controlling a slew rate according to an eighth aspect of the present disclosure.

FIG. 17 is a waveform diagram of each part of FIG. 16.

FIG. 18 is a circuit diagram of a gate driver including a circuit for controlling a slew rate according to the ninth aspect of the present disclosure;

FIG. 19 is a waveform diagram of each part of FIG. 18;

FIG. 20 is a circuit diagram of a gate driver including a circuit for controlling a slew rate according to the tenth aspect of the present disclosure; and

FIG. 21 is a waveform diagram of each part of FIG. 20.

### DETAILED DESCRIPTION

Various aspects according to the spirit of the present disclosure are provided to more fully explain the spirit of the present disclosure to those skilled in the art. The aspects presented in this specification may be modified in various ways, and the scope of the present disclosure is not limited to the aspects presented in this specification. It should be understood that the scope of the present disclosure includes all modifications, equivalents, and alternatives falling within the spirit and technical scope of the present disclosure.

Similar reference numerals are used to refer to similar components in the accompanying drawings. In the accompanying drawings, the dimensions of structures may be enlarged or reduced to facilitate a clear understanding of the present disclosure.

The terminology used herein is solely for the purpose of describing specific aspects and is not intended to limit the present disclosure. The singular form “a” includes the plural form unless the context clearly indicates otherwise. In this specification, terms such as “include” or “have” should be understood to specify the presence of the listed features, but not to preemptively exclude the possibility of the presence or addition of one or more other features. The term “and/or” is used herein to encompass any one of the listed features and any combination of one or more of the listed features.

In this specification, terms such as “first,” “second,” etc. are used solely to distinguish one feature from another to describe various features, and these features are not limited by these terms. If the description below describes a first feature as being connected, coupled, or connected to a second feature, this does not exclude the possibility that a third feature may be interposed between the first and second features.

Unless otherwise defined, the terms described herein, including technical or scientific terms, have the same meaning as commonly understood by one of ordinary skill in the art to which this disclosure pertains. Terms defined in commonly used dictionaries should be interpreted to have a meaning consistent with their meaning in the context of the relevant technology, and will not be interpreted in an idealized or overly formal sense unless expressly defined in this application.

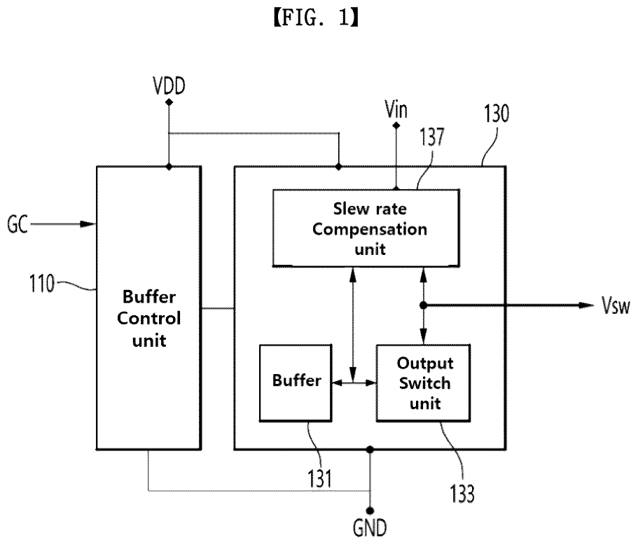

FIG. 1 is a block diagram of a circuit for controlling a slew rate and a gate driver including the circuit, according to an aspect of the present disclosure.

Referring to FIG. 1, a driving circuit for controlling a slew rate and/or a gate driver including the driving circuit include a buffer control unit 110 and a slew rate control unit 130.

The buffer control unit 110 outputs a power supply voltage based on a high-level or low-level control signal (GC: Gate Control).

The slew rate control unit 130 outputs the input power supply voltage as a driving voltage Vsw. At this time, the slew rate may be adjusted during a falling transition (or rising transition) of the driving voltage Vsw.

The buffer control unit 110 may include a plurality of switches and/or a plurality of transistors.

The slew rate control unit 130 may include a buffer unit 131, an output switch unit 133, and a slew rate compensation unit 137.

The buffer unit 131 is connected to an input terminal of the output switch unit 133. The buffer unit 131 may delay and output a signal input to the output switch unit 133 via the buffer control unit 110.

The output switch unit 133 includes an output transistor. The output switch unit 133 may be turned on or off by a signal input via the buffer unit 131 and may output a high-level or low-level driving voltage Vsw.

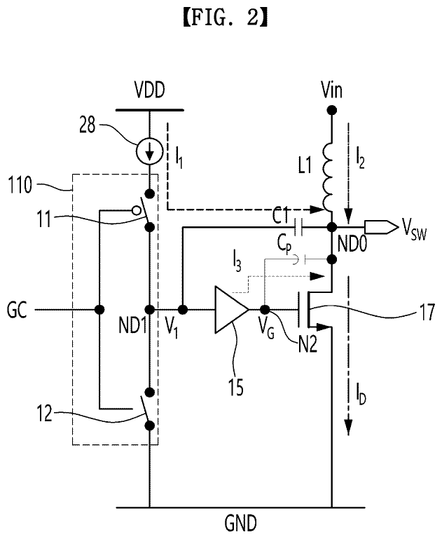

The output switch unit 133 may include output transistors 17, 27, 37, 47, 57, 67, 79, and 89 described below. At this time, the output transistors 17, 27, 37, 47, 57, 67, 79, and 89 may have different driving capabilities due to parasitic capacitance (Cp, FIG. 2) depending on changes in the manufacturing process, operating voltage, operating temperature, etc.

Due to the parasitic capacitance present in the output transistors, when the output transistors are turned on during the rising transition (or falling transition) of the control signal, a difference in the slope of the gate voltage may occur. This difference in the slope of the gate voltage affects the slope of the driving voltage. This gate voltage slope deviation and the driving voltage slope deviation may be provided with different deviation values for each output transistor. Accordingly, the slew rate of the driving voltage output by each output transistor may also vary. Such variations in slew rate may cause deviations in the input/output data of various driving circuits and deteriorate noise characteristics.

Aspects of the present disclosure provide a driving circuit capable of reducing gate voltage slope deviation by controlling the slew rate, and/or a gate driver including the driving circuit. Furthermore, aspects of the present disclosure may suppress electromagnetic interference (EMI) characteristics and prevent an increase in EMI.

The driving circuit for controlling the slew rate disclosed in aspects of the present disclosure may be defined as a gate driver and may be applied to other driving circuits or power management circuits.

The slew rate refers to the rate at which the current or voltage of an output transistor temporarily changes, and may be defined as the maximum value of the change in voltage or current per unit time. This variation in slew rate may affect electromagnetic interference (EMI) characteristics due to the slope deviation of output voltages. In other words, the faster the slew rate, the more abrupt the voltage or current change, which may generate high-frequency signals and increase electromagnetic interference (EMI).

Aspects of the present disclosure may ensure that the driving current of an output transistor, which varies depending on changes in the manufacturing process, operating voltage, operating temperature, etc., is output as a voltage with a constant slew rate. This process may be controlled by a slew rate compensation unit 137. For this purpose, the slew rate compensation unit 137 may include a capacitor. For example, if the capacitance value of the capacitor is set constant, the voltage during a rising or falling transition may be adjusted to have a constant slope. This may reduce the slope deviation of the driving voltage Vsw caused by the output transistors.

The capacitor of the slew rate compensation unit 137 may be connected between the input terminal of the buffer unit 131 and the output terminal (i.e., drain terminal) of the output switch unit 133. One terminal of the capacitor of the slew rate compensation unit 137 may be connected to the input terminal of the buffer unit 131, and the other terminal may be connected to the output terminal of the output switch unit 133. The slew rate compensation unit 137 may adjust the slew rate of the output voltage of the output transistor so that the change in the driving voltage Vsw due to the parasitic capacitance within the output transistor has a constant slope. The slew rate compensation unit 137 may control the delay time of the driving voltage Vsw output from the output switch unit 133.

The capacitor of the slew rate compensation unit 137 is a capacitor C1 described below. The capacitor of the slew rate compensation unit 137 is charged while the driving voltage Vsw makes an upward transition, and when the gate voltage of each output transistor falls, the capacitor reduces the difference (e.g., slope difference) between the driving voltage of each output transistor and the design reference voltage Ref, thereby controlling the slew rate of the driving voltage Vsw. In addition, the capacitor of the slew rate compensation unit 137 is discharged while the driving voltage Vsw makes a downward transition, and when the gate voltage of the output transistor rises, the capacitor reduces the difference (e.g., slope difference) between the driving voltage of each output transistor and the design reference voltage Ref, thereby controlling the slew rate of the driving voltage Vsw. The capacity of the above capacitor C1 may be set to a constant value greater than the capacity of the parasitic capacitance of the output transistor, thereby minimizing changes in the output voltage due to the parasitic capacitance.

Hereinafter, a circuit configuration of a driving circuit for controlling a slew rate and/or a gate driver including the driving circuit will be described.

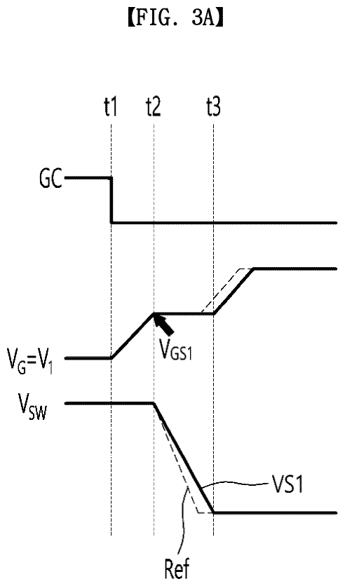

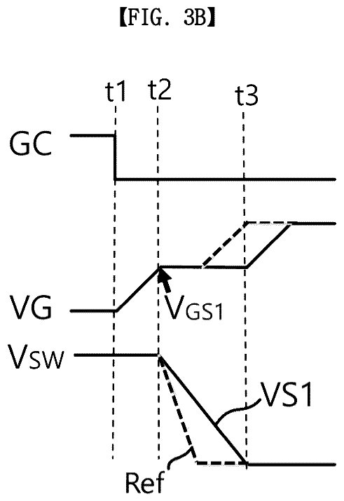

FIG. 2 is a circuit diagram of a circuit for controlling a slew rate and/or a gate driver according to a first aspect of the present disclosure. FIG. 3A is a waveform diagram of each component of FIG. 2, and FIG. 3B is a waveform diagram of a comparative example.

Referring to FIG. 2, the gate driver may include a buffer control unit 110, a buffer 15 as a buffer unit, an output transistor 17 as an output switch unit, and a capacitor C1 as a slew rate compensation unit.

The buffer control unit 110 may include a plurality of switches (e.g., first and second switches 11 and 12). For convenience of explanation, a pair of switches 11 and 12 is illustrated, but other transistors or switches may be connected. Alternatively, the switches may be replaced with transistors or relays.

The first switch 11 is turned on (switch-on) or off (switch-off) by the inverted signal of the control signal GC. A current source 18 connected to the power supply voltage VDD is connected to the input terminal of the first switch 11. The current source 18 generates or provides current that charges the capacitor C1.

The first switch 11 may be turned on or off by the input terminal of the second switch 12 by the control signal GC.

The output terminal of the first switch 11 and the input terminal of the second switch 12 are connected at a first node ND1. Additionally, the input terminal of the buffer 15 and one terminal of the capacitor C1 are connected to the first node ND1. The output terminal of the buffer 15 is connected to the gate terminal of the output transistor 17 and the node N2. The capacitor C1 is electrically connected between the input terminal of the buffer 15 and the output transistor 17. The first node ND1 is the input terminal of the buffer 15. The node N2 is the output terminal of the buffer 15 and may be defined as a “second node.”

The drain terminal of the output transistor 17 is connected to the other terminal of the capacitor C1 and the other terminal of the inductor L1, which is connected to an external power source Vin. A driving voltage Vsw may be output through the output node ND0 of the drain terminal of the output transistor 17. The output transistor 17 may include an NMOS transistor.

The first and second switches 11 and 12 may operate in opposite directions by a control signal GC. For example, when the first switch 11 is in a conducting state by the control signal GC, the second switch 12 is in an open state. Conversely, when the first switch 11 is in an open state, the second switch 12 is in a conducting state. The output terminal of the second switch 12 and the source terminal of the output transistor 17 are connected to a low voltage or ground terminal GND.

The input terminal and the output terminal of the first switch 11 are connected by the low level of the control signal GC, and the power voltage VDD is input to the first node ND1 through the first switch 11. The buffer 15 delays the voltage input through the first node ND1 and transmits it to the gate terminal of the output transistor 17. Here, the current flowing through the current source 18 to the capacitor C1 is defined as the first current I1, the current flowing through the inductor L1 connected to the input power source Vi and the drain terminal of the output transistor 17 is defined as the second current I2, and the current flowing through the buffer 15 to the parasitic capacitance Cp of the output transistor 17 may be defined as the third current I3. Meanwhile, the parasitic capacitance Cp may be a capacitance generated between the gate and drain of the output transistor 17.

When the control signal GC is applied at a low level, the first switch 11 is turned on, and the output transistor 17 is turned on by the high level of the gate voltage VG input through the current source 18 and the first switch 11, and current ID flows from the drain terminal to the source terminal.

On the other hand, when the control signal GC is applied at a high level, the first switch 11 is opened, and the output transistor 17 is turned off by the low level of the gate voltage VG, and the voltage applied to the drain terminal of the output transistor 17 is output as the driving voltage Vsw. When the control signal GC is applied at a low level, the capacitor C1 is charged, and when the control signal GC is applied at a high level, the capacitor C1 is discharged. At this time, when the control signal GC makes a rising transition (change from a low level to a high level) or a falling transition (change from a high level to a low level), the driving voltage Vsw is output with a slope by charging or discharging the capacitor C1.

As shown in FIGS. 2 and 3A, while the control signal GC transitions from a high level to a low level (at time t1), the voltage V1 of the first node ND1 rises at a slope (I1/C1) by sourcing the first current I1 from zero volts (0V) through the capacitor C1. At this time, the voltage VG of the gate terminal of the output transistor 17 rises to the same level as the first voltage V1.

When the voltage VG of the gate terminal of the output transistor 17 reaches the level of the gate-source voltage VGS1, when the current ID flowing from the drain terminal to the source terminal and the second current I2 are equal (VGS1@ID=I2), the driving voltage Vsw begins to transition (fall) from a high level to a low level (at time t2). At this time, when the current ID flowing from the drain terminal to the source terminal of the output transistor 17 is the sum of the first, second, and third currents I1, I2, and I3 (ID=I1+I2+I3), the gate voltage VG of the output transistor 17 becomes the Miller plateau voltage level, and the driving voltage Vsw is reduced to a slope (i.e., I1/C1) by the capacitor C1. That is, as the gate-source voltage VGS1 of the output transistor 17 approaches the Miller plateau voltage level of the output transistor 17, the change in the slope VS1 of the driving voltage Vsw may be constantly controlled by the capacitance value of the capacitor C1. The Miller plateau is a specific region appearing in the voltage-current characteristic curve of the transistor, and represents a state in which the drain current hardly changes with respect to the gate current.

Accordingly, the voltage VG at the gate terminal of the output transistor 17 may be delayed from the initial zero voltage (0V) by the capacitor C1 until the start of the decline of the output voltage Vsw. At this time, since the capacity of the capacitor C1 is set to a constant value (or a value with a small deviation) greater than the capacity of the parasitic capacitance Cp, the slope VS1 of the driving voltage Vsw output from the output transistor 17 in the gate driver may be relatively further reduced compared to the slope VS1 of the conventional method (FIG. 3B) based on the design reference voltage Ref. The slope VS1 changes to the value of I1/C1 from the second time point t2 to the third time point t3 by the capacitor C1.

Since the capacitor C1 has a small deviation, i.e., a small difference in capacity during manufacturing, the slope of the driving voltage of the output transistor may be output at a constant level. In addition, the capacitor C1 may also reduce the deviation between the driving voltages Vsw output from the output transistors of each of the plurality of gate drivers. That is, the present disclosure may reduce the slope deviation of the driving voltage by adding a Miller capacitor between the input and output terminals of the buffer 15. Conventionally, in the circuit of FIG. 2, without the capacitor C1 and the buffer 15, as shown in FIG. 3B, only the parasitic capacitance Cp exists in the output transistor, resulting in a large slope difference from the design reference voltage Ref. Furthermore, the capacitance difference between the parasitic capacitors within the plurality of transistors causes a large slope deviation in the rising or falling sections of the driving voltages, which affects electromagnetic interference (EMI) characteristics.

Table 1 shows the falling point, the slope delay during the falling phase, and the slope of the driving voltage of the output transistor 17 according to the first aspect of the present disclosure. Here, VGS1@ID=I2 represents the drain-gate voltage when the drain current ID and the second current I2 are equal, and VGS1@ID=I1+I2+I3 represents the drain-gate voltage when the drain current ID is equal to the sum of the first, second, and third currents I1, I2, and I3.

TABLE 1

| | |
|---|---|
| Delay in the falling point | {(VGS1@ID = I2) × |
| of the driving voltage (Vsw) | C1}/I1 |
| Delay in the target slope | {(VGS1@ID = I1 + |
| of the driving voltage | I2 + I3) × C1}/I1 |
| dVsw/dt | I1/C1 |

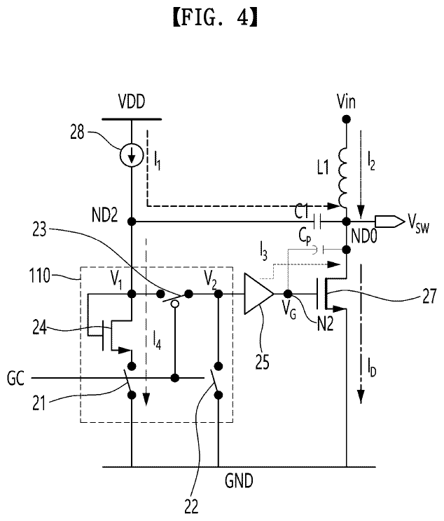

FIG. 4 is a circuit diagram of a circuit for controlling a slew rate according to a second aspect of the present disclosure and/or a gate driver including the same.

Referring to FIG. 4, the gate driver may include a buffer control unit 110, a buffer 25 as a buffer unit, an output transistor 27 as an output switch unit, and a capacitor C1 as a slew rate compensation unit.

The buffer control unit 110 may include at least one transistor 24 and a plurality of switches 21, 22, and 23, for example, first to third switches 21, 22, and 23 and a first transistor 24. The buffer control unit 110 may further be connected to other switches or transistors. The first to third switches 21, 22, and 23 may include transistors or relays. The first transistor 24 may include an NMOS transistor.

The input terminal of the first switch 21 is connected to the source terminal of the first transistor 23. The input terminal of the second switch 22 is connected to the input terminal of the buffer 25. The input terminal of the third switch 23 is connected to the drain terminal of the first transistor 24 and a current source 28 connected to a power supply voltage VDD. The control terminals of the first to third switches 21, 22, and 23 are each connected to a line of a control signal GC. A signal opposite to the signals of the control terminals of the first and second switches 21, and 22 is applied to the control terminal of the third switch 23. The output terminals of the first and second switches 21, and 22 and the source terminal of the output transistor 27 are connected to a low voltage or ground terminal GND.

The drain terminal of the first transistor 24 is connected to the current source 28 connected to the power supply voltage VDD terminal and the input terminal of the third switch 23. The gate terminal of the first transistor 24 is connected to the drain terminal.

One terminal of a capacitor C1 is connected to a first node ND2, which is a point where the current source 28 and the drain terminal of the first transistor 24 are connected. When the first transistor 24 is turned off, the first current I1 passing through the current source 28 may be charged into the capacitor C1.

The input terminal of the buffer 25 is connected to the input terminal of the second switch 22 and the output terminal of the third switch 23. The output terminal of the buffer 25 is connected to the gate terminal of the output transistor 27 and the node N2. The first node ND2 is an input terminal of the buffer 25, and the output node N2 is an output terminal of the buffer 25. One terminal of the inductor L1 is connected to an external power source Vin, and the other terminal is connected to the drain terminal of the output transistor 27. The other terminal of the capacitor C1 is connected to the output terminal of the driving voltage Vsw, the other terminal of the inductor L1, and the drain terminal of the output transistor 27, respectively.

The output transistor 27 has a parasitic capacitance Cp, and the capacity of the parasitic capacitance Cp of the output transistor 27 may have different values depending on the manufacturing process, voltage, or temperature changes of each output transistor 27.

When the control signal GC is at a high level, the first and second switches 21, and 22 are turned on, the input terminal of the first switch 21 is connected to the source terminal of the first transistor 24, and the input terminal of the second switch 22 is connected to the input terminal of the buffer 25. In addition, the third switch 23 is opened. On the other hand, when the control signal GC is at a low level, the first and second switches 21, and 22 are opened, the third switch 23 is turned on, and the power voltage VDD is applied to the buffer 25 through the third switch 23 and the current source 28.

When the control signal GC is at a high level, the first transistor 24 is turned on, allowing current I4 to flow to the ground terminal GND, the first switch 21 and the second switch 22 to be turned on, and the third switch 23 is opened. At this time, the capacitor C1 is charged with current I1 through the current source 28, the output transistor 27 is turned off, and the driving voltage Vsw is output at a high level. Here, one terminal of the capacitor C1 is connected to the first node ND2, and the other terminal is connected to the output node ND0.

On the other hand, when the control signal GC is at a low level, the first transistor 24 is turned off, the first switch 21 and the second switch 22 are opened, and the third switch 23 is turned on. At this time, the output transistor 27 is turned on by the voltage VG of the gate terminal, and the driving voltage Vsw is output at a low level. The current flowing through the current source 28 to the capacitor C1 is defined as the first current I1, the current flowing through the inductor L1 connected to the input power supply and the drain terminal of the output transistor 27 is defined as the second current I2, and the current flowing through the buffer 25 to the parasitic capacitance Cp of the output transistor 27 may be defined as the third current I3.

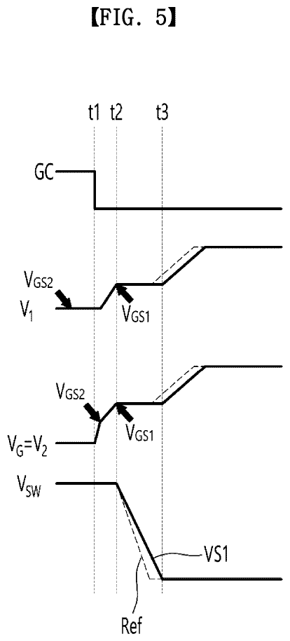

As illustrated in FIGS. 4 and 5, when the control signal GC transitions from a high level to a low level (at time t1), the first voltage V1 at the first node ND2 receives the first current I1 from the gate-source voltage VGS2 terminal until the drain current and the input current I4 of the first transistor 24 become equal (‘VGS2@ID=I1’) and rises with a voltage slope (I1/C1) due to the capacitor C1. That is, the first voltage V1 receives the first current I1 at zero volts during the transition of the control signal GC and rises with a voltage slope (I1/C1) due to the capacitance value of the capacitor C1. After this, the voltage VG at the gate terminal of the output transistor 27 becomes the gate-source voltage VGS1 of the output transistor 27 when the current ID of the driving voltage Vsw is equal to the second current I2 (I2=ID), and at this time, the driving voltage Vsw begins to fall (time point t2).

The voltage VG at the gate terminal of the output transistor 27 becomes the gate-source voltage VGS1 of the output transistor 27 when the current ID at the drain terminal of the output transistor 27 becomes equal to the sum of the first, second, and third currents I1, I2, and I3 (at time t2, ID=I1+I2+I3), and the gate voltage becomes the Miller plateau voltage of the output transistor 27 and may be reduced to the slope VS1 of the driving voltage Vsw output from the output transistor 27, i.e., I1/C1. That is, as the gate-source voltage VGS1 of the output transistor 27 approaches the Miller plateau voltage of the output transistor 27, the capacitor C1 begins to discharge current. The slope VS1 changes to the value of I1/C1 from the second time point t2 to the third time point t3 by the capacitor C1.

Therefore, the voltage VG at the gate terminal of the output transistor 27 is not zero volts, but rises from the gate-source voltage VGS2 of the first transistor 24 and is delayed until the start of the falling transition of the driving voltage Vsw. Accordingly, the initial entrance slope of the gate-source voltage of the output transistor 27 may be increased by the first transistor 24, and the delay time until the falling transition of the driving voltage may be reduced. In FIG. 5, VGS1 represents the gate-source voltage of the output transistor, and VGS2 represents the gate-source voltage of the first transistor.

The capacitor C1 has little variation (i.e., a difference in capacity during manufacturing), so that the slope of the driving voltage of the output transistor may be output consistently. Additionally, the capacitor may also reduce the deviation between the driving voltages Vsw output from the output transistors of each of the plurality of gate drivers. That is, the present disclosure may reduce the slope deviation of the driving voltage by adding a Miller capacitor C1 between the input and output terminals of the buffer 15. Furthermore, the slope deviation between the gate voltages VG and the slope deviation between the driving voltages Vsw between the transistors within the plurality of gate driver circuits may also be reduced.

Table 2 shows the starting point, the slope delay, and the slope of the driving voltage of the output transistor 27 according to the second aspect of the present disclosure. Here, VGS1@ID=I2 represents the drain-gate voltage when the drain current ID and the second current I2 are equal, VGS1@ID=I1+I2+I3 represents the drain-gate voltage when the drain current ID is equal to the sum of the first, second, and third currents I1, I2, and I3, and ‘x’ represents multiplication.

TABLE 2

| | |
|---|---|
| Delay in the falling point | {(VGS1@ID = I2) × |
| of the driving voltage (Vsw) | C1}/I1 |
| Delay in the target slope | {(VGS1@ID = I1 + |
| of the driving voltage | I2 + I3) × C1}/I1 |
| dVsw/dt | I1/C1 |

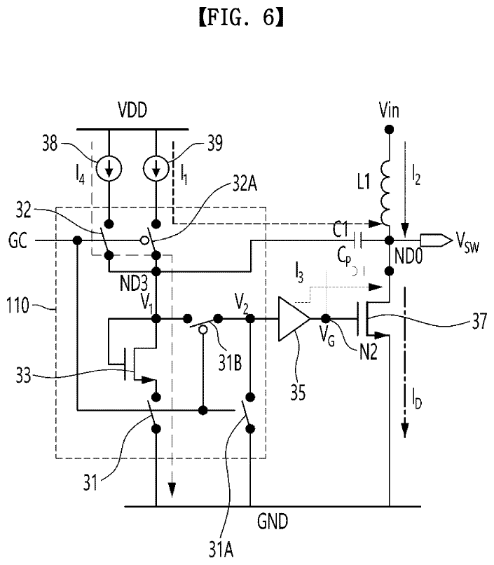

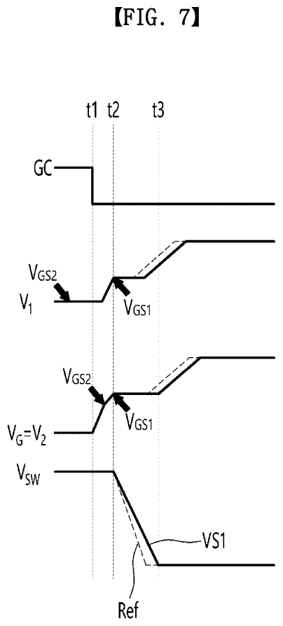

FIG. 6 is a circuit diagram of a circuit for controlling a slew rate according to a third aspect of the present disclosure and/or a gate driver including the same, and is a waveform diagram of each part of FIG. 6 in FIG. 7.

Referring to FIGS. 6 and 7, the gate driver may include a buffer control unit 110, a buffer 35 as a buffer unit, an output transistor 37 as an output switch unit, and a capacitor C1 as a slew rate compensation unit.

The buffer control unit 110 may include at least one transistor 33 and a plurality of switches 31, 31A, 31B, 32, and 32A. For example, the buffer control unit 110 may include a first transistor 33 and first to fifth switches 31, 31A, 31B, 32, and 32A. At this time, other switches or transistors may be further connected to the buffer control unit 110. Transistors or relays may be further connected to the first to fifth switches 31, 31A, 31B, 32, and 32A. The first transistor 33 may include an NMOS transistor.

The input terminal of the first switch 31 is connected to the source terminal of the first transistor 33, the input terminal of the second switch 31A is connected to the input terminal of the buffer 35, and the input terminal of the third switch 31B is connected to the drain terminal of the first transistor 33. The source terminals of the first and second switches 31 and 31A and the output transistor 37 may be connected to a low voltage VGL or ground terminal.

The gate terminal and drain terminal of the first transistor 33 are connected to each other, and the output terminals of the fourth and fifth switches 32 and 32A are connected to the drain terminal of the first transistor 33. The input terminals of the fourth and fifth switches 32 and 32A are connected to respective current sources 38 and 39 connected to the power supply voltage VDD.

One terminal of the capacitor C1 is connected to the drain terminal of the first transistor 33. One terminal of the capacitor C1 is connected to the drain terminal of the first transistor 33 and the output terminals of the fourth and fifth switches 32 and 32A.

One terminal of the capacitor C1 is connected to a first node ND3, which is a node where a current source 28 and the drain terminal of the first transistor 33 are connected. The capacitor C1 may be charged with a first current I1 input through at least one of the plurality of current sources 28 and discharged by the operation of the output transistor 27.

The input terminal of the buffer 35 is connected to the input terminal of the second switch 31A and the output terminal of the second switch 31B, and the output terminal of the buffer 35 is connected to the gate terminal of the output transistor 37 and the node N2. One terminal of the inductor L1 is connected to an external power source Vin, and the other terminal is connected to the drain terminal of the output transistor 37. The first node ND3 is the input terminal of the buffer 35, and the node N2 is the output terminal of the buffer 35. The other terminal of the capacitor C1 is connected to the output terminal of the driving voltage Vsw, the output terminal of the inductor L1, and the drain terminal of the output transistor 37.

The output transistor 37 has a parasitic capacitance Cp. The capacitance of the parasitic capacitance Cp of the output transistor 37 may have different values depending on the manufacturing process of the output transistor 37, voltage, or temperature changes.

The first to fifth switches 31, 31A, 31B, 32, and 32A are each connected to the line of the control signal GC and operate in a conducting or open state. For example, the first, second, and fourth switches 31, 31A, and 32 may be turned on and the third and fifth switches 31B and 32A may be opened by a high level of the control signal GC. The first, second, and fourth switches 31, 31A, and 32 may be opened and the third and fifth switches 31B and 32A may be turned on by a low level of the control signal GC.

When the control signal GC is at a high level, the first transistor 33 is turned on by the first voltage V1 input by the first and fourth switches 31 and 32, the first current source 38 flows as a fourth current I4 through the first transistor 33, and the driving voltage Vsw of the output transistor 37 is output at a high level.

When the control signal GC is at a low level, the third and fifth switches 31B and 32A are connected to the input terminal, the first transistor 33 is turned off, and the first current I1 is supplied to the capacitor C1 through the second current source 39 and supplied to the input terminal of the buffer 35 through the third switch 31B. The output transistor 37 is turned on by the voltage VG applied through the buffer 35, and the driving voltage Vsw is output at a low level.

The current flowing through the second current source 39 to the capacitor C1 is the first current I1, the current flowing through the inductor L1 connected to the input power source Vin and the drain terminal N1 of the output transistor 37 is the second current I2, and the current flowing through the buffer 35 to the parasitic capacitance Cp of the output transistor 37 is the third current I3.

As shown in FIGS. 6 and 7, when the control signal GC transitions from a high level to a low level (at time t1), the first voltage V1 at the first node ND3, which is one terminal of the capacitor C1, increases from the gate-source voltage VGS2 of the first transistor 33 to a slope (I1/C1) due to the capacitor C1 until the drain current ID of the first transistor 33 reaches a fourth current (‘ID=I4’). Thereafter, the gate voltage VG of the output transistor 37 increases to the same level as the first voltage V1. And the gate voltage VG of the output transistor 37 becomes the gate-source voltage VGS1 of the output transistor 27 when the current ID of the driving voltage Vsw becomes equal to the second current I2 (‘ID=I2’), and at this time, the driving voltage Vsw transitions (i.e., falls) from a high level to a low level (time point t2).

Afterwards, the voltage VG of the gate terminal of the output transistor 37 becomes the gate-source voltage VGS1 of the output transistor 37 when the current ID of the drain terminal of the output transistor 37 becomes equal to the sum of the first, second, and third currents I1, I2, and I3 (ID=I1+I2+I3), and the gate voltage becomes the Miller plateau voltage of the output transistor 37 and may be reduced to the slope VS1 of the driving voltage Vsw output from the output transistor 37, i.e., I1/C1. That is, as the gate-source voltage VGS1 of the output transistor 37 approaches the Miller plateau voltage of the output transistor 37, the capacitor C1 begins to discharge current. The slope VS1 changes to the value of I1/C1 from the second time point t2 to the third time point t3 by the capacitor C1.

Therefore, the voltage VG at the gate terminal of the output transistor 37 rises from the gate-source voltage VGS2 of the first transistor 33 rather than zero volts, and is delayed until the start of the falling transition of the driving voltage Vsw. Accordingly, the initial level of the gate-source voltage of the output transistor 37 may be controlled by the first transistor 33, and the delay until the falling transition of the driving voltage may be reduced compared to the aspect of FIG. 2.

The capacitor C1 has less variation, i.e., less capacitance difference during manufacturing, so that the slope of the driving voltage of the output transistor may be output consistently. Furthermore, the variation between the driving voltages Vsw output from each output transistor of multiple gate drivers may also be reduced. That is, the present disclosure may reduce the slope deviation of the driving voltage by adding a Miller capacitor C1 between the input and output terminals of the buffer 15. Furthermore, the slope deviation between gate voltages VG and between driving voltages Vsw between transistors within multiple gate driver circuits may be reduced.

Table 3 shows the falling point, the slope delay during the falling point, and the slope of the driving voltage of the output transistor 37 according to the third aspect of the present disclosure. Here, VGS1@ID=I2 represents the drain-gate voltage when the drain current ID of the output transistor is equal to the second current I2. VGS1@ID=I1 represents the drain-gate voltage when the drain current ID of the output transistor is equal to the first current I1. VGS1@ID=I1+I2+I3 represents the drain-gate voltage when the drain current ID is equal to the sum of the first, second, and third currents I1, I2, and I3.

TABLE 3

| | |
|---|---|
| Delay in the falling point | {((VGS1@ID = I2) − |
| of the driving voltage (Vsw) | (VGS2@ID = I1)) × C1}/I1 |
| Delay in the target slope | {(VGS1@ID = I1 + |
| of the driving voltage | I2 + I3) × C1}/I1 |
| dVsw/dt | I1/C1 |

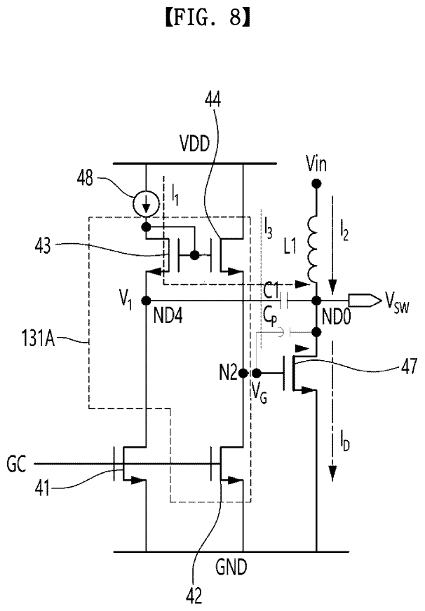

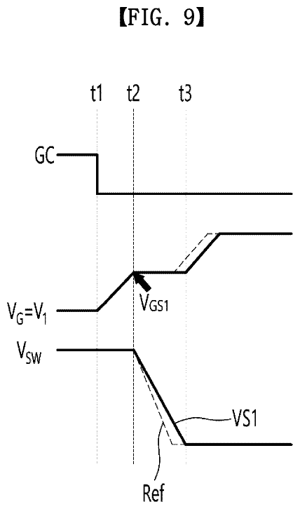

FIG. 8 is a circuit diagram of a circuit for controlling a slew rate according to a fourth aspect of the present disclosure, or a gate driver including the same, and FIG. 9 is a waveform diagram of each component of FIG. 8.

Referring to FIG. 8, the gate driver may include a first transistor 41 as a buffer control unit, an output transistor 47 as an output switch unit, a buffer unit 131A including a plurality of transistors 42, 43, and 44, and a capacitor C1 as a slew rate compensation unit.

The buffer unit 131A is connected between the first transistor 41 and the output transistor 47, and may include second to fourth transistors 42, 43, and 44. Other switches or transistors may be further connected to the first transistor 41. The first to fourth transistors 41, 42, 43, and 44 may include NMOS transistors.

The gate terminals of the first and second transistors 41 and 42 are simultaneously applied with the control signal GC, and the source terminals of the first and second transistors 41 and 42 and the output transistor 47 are connected to a low voltage or a ground terminal GND.

The drain terminal of the first transistor 41 is connected to the source terminal of the third transistor 43, and the drain terminal of the second transistor 42 is connected to the source terminal of the fourth transistor 44. A PMOS transistor or an NMOS transistor may be further connected to at least one of the first to fourth transistors 41, 42, 43, and 44.

Here, the gate terminal of one of the third and fourth transistors 43 and 44 is connected to a current source 48, and the third and fourth transistors 43 and 44 may function as current mirrors. For example, the gate terminals of the third and fourth transistors 43 and 44 are connected to the drain terminal of the third transistor 43, the drain terminal of the third transistor 43 is connected to a current source 48 that supplies a power voltage VDD, and the drain terminal of the fourth transistor 44 is connected to the power voltage VDD.

The drain terminal of the second transistor 42 and the source terminal of the fourth transistor 44 may be connected to a node N2 connected to the gate terminal of the output transistor 47. A parasitic capacitance Cp exists between the gate terminal and drain terminal of the output transistor 47. The capacity of this parasitic capacitance Cp may vary and not have the same value depending on the manufacturing process, operating voltage, and operating temperature of each transistor.

One terminal of the capacitor C1 is connected to a first node ND4, which is a node connecting the drain terminal of the first transistor 41 and the source terminal of the third transistor 43. The capacitor C1 may be charged by a first current I1 supplied through the third transistor 43 and discharged by the operation of the output transistor 47. The other terminal of the capacitor C1 may be connected to the output terminal of the inductor L1 and the drain terminal of the output transistor 47. The drain terminal of the output transistor 47 outputs a driving voltage Vsw through the output node ND0 connected to the drain terminal of the output transistor 47 and the other terminal of the capacitor C1. The first node ND4 is an input terminal of the buffer unit 131A.

The first and second transistors 41 and 42 may operate simultaneously by the control signal GC. For example, the first and second transistors 41 and 42 are turned on by the high level of the control signal GC, the third and fourth transistors 43 and 44 are turned on by the power supply voltage VDD, the output transistor 47 is turned off, and the driving voltage Vsw is output at a high level.

The first and second transistors 41 and 42 are turned off by the low level of the control signal GC, the third and fourth transistors 43 and 44 are turned on by the power supply voltage VDD, the output transistor 47 is turned on, and the driving voltage Vsw outputs a low level.

When the first and second transistors 41 and 42 are turned off and the third and fourth transistors 43 and 44 are turned on, the power supply voltage VDD through the third transistor 43 is charged to the capacitor C1. At this time, the current flowing to the charged capacitor C1 is the first current I1. In addition, the power supply voltage VDD flowing through the fourth transistor 44 flows to the gate terminal of the output transistor 47. At this time, the current flowing through the parasitic capacitance Cp of the output transistor 47 is the third current I3. Furthermore, the current flowing to the output node ND0 through the inductor L1 connected to the external power source Vin may also be the third current I3.

As shown in FIGS. 8 and 9, when the control signal GC transitions from a high level to a low level (at time t1), the first voltage V1 at one terminal of the capacitor C1 receives the first current I1 from zero volts and rises Rs with a slope (I1/C1) due to the capacitor C1. Thereafter, the gate voltage VG of the output transistor 47 rises to the same level as the first voltage V1.

When the current ID of the driving voltage Vsw is equal to the second current I2, the gate voltage VG of the output transistor 47 becomes the gate-source voltage VGS1 of the output transistor 47, and the driving voltage Vsw begins to transition, i.e., to fall (at time t2).

Thereafter, the voltage VG of the gate terminal of the output transistor 47 becomes the gate-source voltage VGS1 of the output transistor 47 when the current ID of the drain terminal of the output transistor 47 becomes equal to the sum of the first, second, and third currents I1, I2, and I3 (ID=I1+I2+I3), and the gate voltage becomes the Miller plateau voltage of the output transistor 47 and may be reduced to the slope (i.e., I1/C1) of the driving voltage Vsw output from the output transistor 47. That is, as the gate-source voltage VGS of the output transistor 47 approaches the Miller plateau voltage of the output transistor 47, the capacitor C1 begins to discharge current.

Accordingly, the voltage VG at the gate terminal of the output transistor 47 rises from zero volts and is delayed until the start of the falling transition of the driving voltage Vsw. The capacitor C1 has a small deviation, i.e., a difference in capacity during manufacturing, so that the slope of the driving voltage of the output transistor may be output consistently. Furthermore, the deviation between the driving voltages Vsw output from each output transistor of the plurality of gate drivers may be reduced. That is, the present disclosure may reduce the slope deviation of the driving voltage by adding a Miller capacitor C1 between the input terminal and the output terminal of the buffer 15. Furthermore, the slope deviation between the gate voltages VG and the slope deviation between the driving voltages Vsw between the transistors within the plurality of gate driver circuits may be reduced.

Table 4 shows the starting point, the slope delay during the falling time, and the slope of the driving voltage of the output transistor 17 according to the fourth aspect of the present disclosure. Here, VGS1@ID=I2 represents the drain-gate voltage when the drain current ID and the second current I2 are equal, and VGS1@ID=I1+I2+I3 represents the drain-gate voltage when the drain current ID is equal to the sum of the first, second, and third currents I1, I2, and I3.

TABLE 4

| | |
|---|---|
| Delay in the falling point | {(VGS1@ID = I2) × C1}/I1 |
| of the driving voltage (Vsw) | |
| Delay in the target slope | {(VGS1@ID = I1 + |
| of the driving voltage | I2 + I3) × C1}/I1 |
| dVsw/dt | I1/C1 |

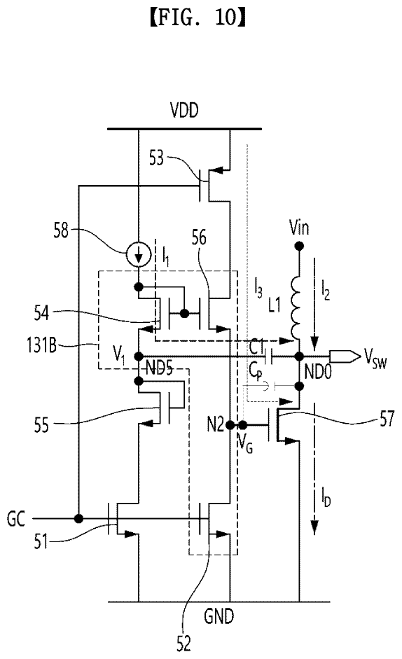

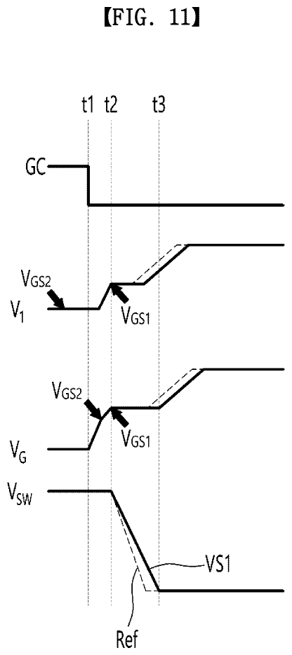

FIG. 10 is a circuit diagram of a circuit for controlling a slew rate according to a fifth aspect of the present disclosure, or a gate driver including the same, and FIG. 11 is a waveform diagram of each component of FIG. 10. FIG. 10 is a modified example of FIG. 8. Referring to FIG. 10, it may be seen that the initial ramp slope of the gate-source voltage of the output transistor may be increased.

Referring to FIG. 10, the gate driver may include a buffer control unit or buffer control circuit including a plurality of transistors 51, 53, and 55, an output transistor 57 as an output switch unit, a buffer unit 131B or buffer circuit, and a capacitor C1 as a slew rate compensation unit.

The buffer control unit may include a plurality of transistors, for example, first, third, and fifth transistors 51, 53, and 55. The buffer control unit may further be connected to other switches or transistors. The buffer unit 131B or buffer circuit may include second, fourth, and sixth transistors 52, 54, and 56. The first, second, fourth, fifth, and sixth transistors 51, 52, 54, 55, and 56 may include NMOS transistors, and the third transistor 53 may include a PMOS transistor. A PMOS transistor or an NMOS transistor may further be connected to at least one of the first to sixth transistors 51, 52, 53, 54, 55, and 56. The fourth and sixth transistors 54 and 56 may function as current mirrors.

The control signal GC is simultaneously applied to the gate terminals of the first, second, and third transistors 51, 52, and 53, and the source terminals of the first and second transistors 51 and 52 and the output transistor 57 are connected to a low voltage or a ground terminal GND.

The drain terminal of the first transistor 51 is connected to the source terminal of the fifth transistor 55. The gate terminal and drain terminal of the fifth transistor 55 are connected to each other. The source terminal of the fourth transistor 54 is connected to the first node ND5 to which the gate terminal and drain terminal of the fifth transistor 55 are connected. The drain terminal of the second transistor 52 is connected to the gate terminal of the output transistor 57. The drain terminal of the second transistor 52 and the gate terminal of the output transistor 57 are connected to the node N2 and the source terminal of the sixth transistor 56. The first node ND5 is an input terminal of the buffer unit 131B.

The source terminal of the third transistor 53 is connected to the power supply voltage VDD terminal. The drain terminal of the third transistor 53 is connected to the drain terminal of the sixth transistor 56. The gate terminal and drain terminal of the fourth transistor 54 and the gate terminal of the sixth transistor 56 are connected to each other.

Either of the gate terminals of the fourth and sixth transistors 54 and 56 may be connected to a current source 58. For example, the gate terminals of the fourth and sixth transistors 54 and 56 may be connected to the drain terminal of the fourth transistor 54. The drain terminal of the fourth transistor 54 may be connected to a current source 58 connected to a power supply voltage VDD. The gate terminal of the output transistor 57 is connected to a node N2, and the drain terminal is connected to an output node ND0 to which the other terminal of the capacitor C1 is connected.

The source terminal of the sixth transistor 56 and the drain terminal of the second transistor 52 may be connected to a node N2, i.e., an input node. At this time, the input node N2 may be connected to the gate terminal of the output transistor 57. A parasitic capacitance Cp exists between the gate terminal and the drain terminal of the output transistor 57. The capacity of this parasitic capacitance Cp may not have the same value and may vary depending on the manufacturing process, operating voltage, operating temperature, etc. of each transistor.

One terminal of the capacitor C1 is connected to a first node ND5 to which the drain terminal of the fifth transistor 55 and the source terminal of the fourth transistor 54 are connected. The capacitor C1 may be charged with a first current I1 through the fourth transistor 54 and discharged by the operation of the output transistor 57. The other terminal of the capacitor C1 may be connected to the output terminal of the inductor L1 and the drain terminal of the output transistor 57. A driving voltage Vsw may be output through an output node ND0 to which the drain terminal of the output transistor 57 and the other terminal of the capacitor C1 are connected.

The first and second transistors 51 and 52 may be operated simultaneously by the control signal GC. For example, the first, second, fourth, and fifth transistors 51, 52, 54, and 55 are turned on by the high level of the control signal GC, and the third and sixth transistors 53 and 56 are turned off. At this time, the output transistor 57 is turned off, and the driving voltage Vsw is output at a high level.

The first, second, fourth, and fifth transistors 51, 52, 54, and 55 are turned off by the low level of the control signal GC, and the third and sixth transistors 53 and 56 are turned on. At this time, the output transistor 57 is turned on. In addition, the first current I1 flows to the capacitor C1 through the fourth transistor 54, and the power voltage output through the sixth transistor 56 is input to the gate terminal of the output transistor 57, so that the output transistor 57 is turned on. At this time, a low level is output to the output node ND0 of the drain terminal of the output transistor 57. A third current I3 flows through the parasitic capacitance Cp of the output transistor 57. In addition, the current of the power voltage flowing to the output node ND0 through the inductor L1 connected to the external power source Vin may be a second current I2.

As shown in FIGS. 10 and 11, since the current from the drain terminal of the fifth transistor 55 flows to the capacitor C1, the first voltage V1 at the first node ND5 receives the first current I1 from the gate-source voltage VGS2 of the fifth transistor 55 and rises with a slope due to the capacitor C1. At this time, the first voltage V1 rises with a slope of I1/C1 due to the fifth transistor 55. That is, when the control signal GC transitions from a high level to a low level (time t1), the first voltage V1 is charged with the power supply voltage VDD with a slope due to the capacitance value (I1/C1) of the capacitor C1. Thereafter, the gate voltage VG of the output transistor 57 rises to the same level as the first voltage V1.

When the current ID of the driving voltage Vsw is equal to the second current I2, the gate voltage VG of the output transistor 57 becomes the gate-source voltage VGS1 of the output transistor 57, and the driving voltage Vsw begins to fall (at time t2).

And the voltage VG of the gate terminal of the output transistor 57 becomes the gate-source voltage VGS1 of the output transistor 57 when the current ID of the drain terminal of the output transistor 57 becomes equal to the sum of the first, second, and third currents I1, I2, and I3 (time point t2, ID=I1+I2+I3), and the gate voltage becomes the Miller plateau voltage of the output transistor 57 and may be reduced to the slope VS1 of the driving voltage Vsw output from the output transistor 57, i.e., I1/C1. That is, as the gate-source voltage VGS1 of the output transistor 57 approaches the Miller plateau voltage of the output transistor 57, the capacitor C1 begins to discharge current. The slope VS1 may increase the initial gate-source voltage slope of the output transistor 57 by the fifth transistor 55, and change to the value of I1/C1 from the second time point t2 to the third time point t3 by the capacitor C1, thereby reducing the difference from the design reference voltage Ref.

Accordingly, the voltage VG at the gate terminal of the output transistor 57 may rise from the gate-source voltage VGS2 of the fifth transistor 55 and be delayed until the start time point t2 of the falling transition of the driving voltage Vsw. Accordingly, the gate voltage of the output transistor 57 is delayed until the falling transition of the driving voltage Vsw begins due to the rise in the gate-source voltage VGS2 of the fifth transistor 55, and may be reduced compared to the delay of FIG. 2.

The capacitor C1 has a small deviation, that is, a small difference in capacity during manufacturing, so that the slope of the driving voltage of the output transistor may be output consistently. In addition, the deviation between the driving voltages Vsw output from the output transistors of each of the plurality of gate drivers may also be reduced. That is, the present disclosure may reduce the slope deviation of the driving voltage by adding a Miller capacitor C1 between the input terminal and the output terminal of the buffer circuit. In addition, the slope deviation between the gate voltages VG and the slope deviation between the driving voltages Vsw between the transistors in the plurality of gate driver circuits may be reduced.

Table 5 shows the starting point, the slope delay during the falling time, and the slope of the driving voltage of the output transistor 57 according to the fifth aspect of the present disclosure. Here, VGS1@ID=I2 represents the drain-gate voltage when the drain current ID and the second current I2 are equal, and VGS1@ID=I1+I2+I3 represents the drain-gate voltage when the drain current ID is equal to the sum of the first, second, and third currents I1, I2, and I3.

TABLE 5

| | |
|---|---|
| Delay in the falling point | {(VGS1@ID = I2) × C1}/I1 |
| of the driving voltage (Vsw) | |
| Delay in the target slope | {(VGS1@ID = I1 + |
| of the driving voltage | I2 + I3) × C1}/I1 |
| dVsw/dt | I1/C1 |

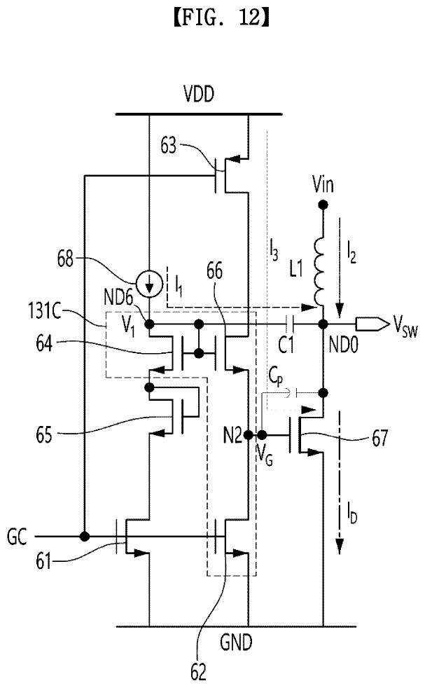

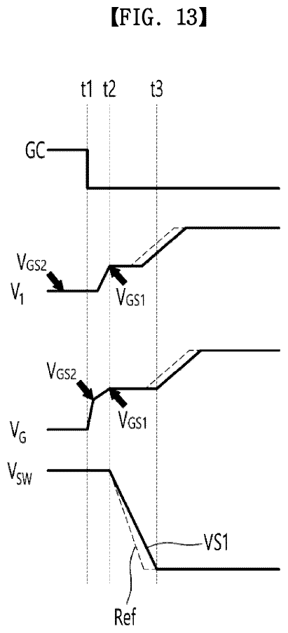

FIG. 12 is a circuit diagram of a circuit for controlling a slew rate according to a sixth aspect of the present disclosure, or a gate driver including the same, and FIG. 13 is a waveform diagram of each part of FIG. 12.

Referring to FIG. 12, the gate driver may include a buffer control unit including a plurality of transistors 61, 63, and 65, an output transistor 67 as an output switch unit, a buffer unit 131C or a buffer circuit, and a capacitor C1 as a slew rate compensation unit.

The buffer control unit may include a plurality of transistors, for example, first, third, and fifth transistors 61, 63, and 65. Other switches or transistors may be further connected to the buffer control unit. The buffer unit 131C or buffer circuit may include second, fourth, and sixth transistors 62, 64, and 66. The first, second, fourth, fifth, and sixth transistors 61, 62, 64, 65, and 66 may include NMOS transistors, and the third transistor 63 may include a PMOS transistor. A PMOS transistor or an NMOS transistor may be further connected to at least one of the first to sixth transistors 61, 62, 63, 64, 65, and 66. The fourth and sixth transistors 64 and 66 may function as current mirrors.

The control signal GC is simultaneously applied to the gate terminals of the first, second, and third transistors 61, 62, and 63, and the source terminals of the first and second transistors 61 and 62 and the output transistor 67 are connected to a low voltage or ground terminal GND.

The drain terminal of the first transistor 61 is connected to the source terminal of the fifth transistor 65, the gate terminal and drain terminal of the fifth transistor 65 are connected to each other, and the source terminal of the fourth transistor 64 is connected to the node where the gate terminal and drain terminal of the fifth transistor 65 are connected. A current source 68 connected to a power supply voltage VDD is connected to the drain terminal of the fourth transistor 64.

The drain terminal of the second transistor 62 is connected to the gate terminal of the output transistor 67, and the node N2 where the drain terminal of the second transistor 62 and the gate terminal of the output transistor 67 are connected is connected to the source terminal of the sixth transistor 66.

The first node ND6 to which the drain terminal of the fourth transistor 64 and one terminal of the capacitor C1 are connected is an input node and is connected to the power supply 68. The capacitor C1 may be connected to the drain terminal and the gate terminal of the fourth transistor 64, the gate terminal of the sixth transistor 66, and the drain terminal of the output transistor 67. A PMOS transistor or an NMOS transistor may further be connected to the source terminal or the drain terminal of the sixth transistor 66. The first node ND6 is an input terminal of the buffer unit 131C.

The gate terminal of the output transistor 67 is connected to the node N2, and the drain terminal is connected to the output node ND0 to which the other terminal of the capacitor C1 is connected.

The drain terminal of the fourth transistor 64 is connected to one terminal of the capacitor C1, thereby providing a path for the first current I1 to the capacitor C1. The connection node N2 to which the source terminal of the sixth transistor 66 and the drain terminal of the second transistor 62 are connected may be connected to the gate terminal of the output transistor 67. A parasitic capacitance Cp exists between the gate terminal and the drain terminal of the output transistor 67. The capacity of this parasitic capacitance Cp may not have the same value and may vary depending on changes in the manufacturing process, operating voltage, and operating temperature of each transistor.

One terminal of the capacitor C1 is connected to the first node ND6 to which the drain terminal of the fourth transistor 64 is connected, and the capacitor C1 may be charged with a first current I1 through a current source 68 and discharged by the operation of the output transistor 67. The other terminal of the capacitor C1 may be connected to the other terminal of the inductor L1 and the drain terminal of the output transistor 67. The drain terminal of the output transistor 67 outputs a driving voltage Vsw through the output node ND0.

The first and second transistors 61 and 62 may be operated simultaneously by the control signal GC. For example, the first, fourth, and fifth transistors 61, 64, and 65 are turned on by the high level of the control signal GC, the second, third, and sixth transistors 62, 63, and 66 are turned off, and the output transistor 67 is turned off. At this time, the first current I1 flows from the current source 68 to the capacitor C1, and the driving voltage Vsw is output at a high level.

The first, fourth, and fifth transistors 61, 64, and 65 are turned off by the low level of the control signal GC, the second, third, and sixth transistors 62, 63, and 66 are turned on, and the output transistor 67 is turned on. At this time, the third current I3 is input to the gate terminal of the output transistor 67 through the sixth transistor 66 and flows to the parasitic capacitance Cp. The driving voltage Vsw is output at a low level to the output node ND0 of the drain terminal of the output transistor 67.

The second current I2 flowing to the output node ND0 through the inductor L1 connected to the external power source Vin flows along a path set according to the turn-on or turn-off of the output transistor 67. For example, when the output transistor 67 is turned on, the current ID flows from the drain terminal to the source terminal through the output transistor 67.

As shown in FIGS. 12 and 13, when the control signal GC transitions from a high level to a low level (at time t1), the first voltage V1 at one terminal of the capacitor C1 receives the first current I1 from the gate-source voltage VGS2 of the fifth transistor 65 and rises Rs with a slope (I1/C1) due to the capacitor C1. That is, when the control signal GC transitions from a high level to a low level (at time t1), the first voltage V1 is charged with the power supply voltage VDD with a slope due to the capacitance value (I1/C1) of the capacitor C1. Thereafter, the gate voltage VG of the output transistor 67 rises to the same level as the first voltage V1. The gate voltage VG of the output transistor 67 becomes the gate-source voltage VGS1 of the output transistor 67 when the current ID of the driving voltage Vsw is equal to the second current I2, and the driving voltage Vsw begins to fall (at time t2).

And the voltage VG of the gate terminal of the output transistor 67 becomes the gate-source voltage VGS1 of the output transistor 67 when the current ID of the drain terminal of the output transistor 67 becomes equal to the sum of the first, second, and third currents I1, I2, and I3 (at time t2, ID=I1+I2+I3), and the gate voltage becomes the Miller plateau voltage of the output transistor 67 and may be reduced to the slope VS1 of the driving voltage Vsw output from the output transistor 67, that is, I1/C1. That is, as the gate-source voltage VGS1 of the output transistor 67 approaches the Miller plateau voltage of the output transistor 67, the capacitor C1 begins to discharge current. The slope VS1 may be increased by the initial entry slope of the gate-source voltage of the output transistor 67 by the fifth transistor 65, and may be changed to the value of I1/C1 from the second time point t2 to the third time point t3 by the capacitor C1, thereby reducing the difference from the design reference voltage Ref.

Therefore, the voltage VG at the gate terminal of the output transistor 67 rises from the gate-source voltage VGS2 of the fifth transistor 65 and is delayed until the start time point t2 of the falling transition of the driving voltage Vsw. Accordingly, the voltage VG at the gate terminal of the output transistor 67 is delayed until the gate-source voltage VGS2 of the fifth transistor 65 rises and the driving voltage Vsw begins to fall, and this delay may be reduced compared to the delay in FIG. 2.

The capacitor C1 has a small variation, i.e., a difference in capacity during manufacturing, so that the slope of the driving voltage of the output transistor may be consistently output. In addition, the variation between the driving voltages Vsw output from the output transistors of each of the plurality of gate drivers may also be reduced. That is, the present disclosure may reduce the slope variation of the driving voltage by adding a Miller capacitor C1 between the input terminal and the output terminal of the buffer circuit. In addition, the slope variation between the gate voltages VG and the slope variation between the driving voltages Vsw caused by the transistors within the plurality of gate driver circuits may be reduced. The above slope VS1 changes to the value of I1/C1 from the second time point t2 to the third time point t3 by the capacitor C1, and may reduce the difference from the design reference voltage Ref.

Table 6 shows the falling time point, the slope delay during the falling time, and the slope of the driving voltage of the output transistor 67 according to the sixth aspect of the present disclosure. Here, VGS1@ID=I2 represents the drain-gate voltage when the drain current ID and the second current I2 are equal, and VGS1@ID=I1+I2+I3 represents the drain-gate voltage when the drain current ID is equal to the sum of the first, second, and third currents I1, I2, and I3.

TABLE 6

| | |
|---|---|
| Delay in the falling point | {(VGS1@ID = I2) × C1}/I1 |
| of the driving voltage (Vsw) | |
| Delay in the target slope | {(VGS1@ID = I1 + |
| of the driving voltage | I2 + I3) × C1}/I1 |
| dVsw/dt | I1/C1 |

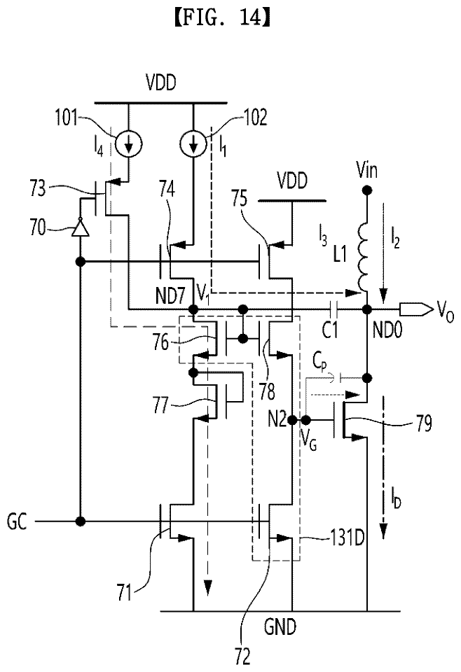

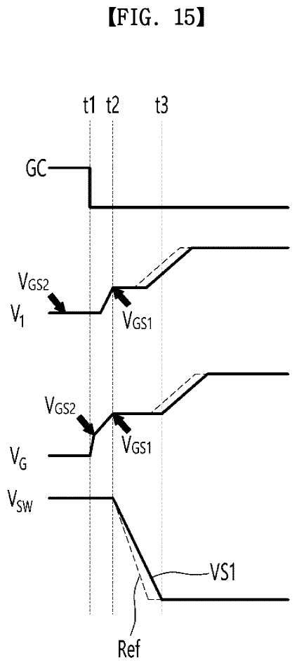

FIG. 14 is a circuit diagram of a circuit for controlling a slew rate according to a seventh aspect of the present disclosure, or a circuit configuration of a gate driver including the same, and FIG. 15 is a waveform diagram of each part of FIG. 14.

Referring to FIG. 14, the gate driver may include a buffer control unit or buffer control circuit including a plurality of transistors 71, 72, 73, 74, 75, and 77 and an inverter 70, an output transistor 79 as an output switch unit, a buffer unit 131D or buffer circuit, and a capacitor C1 as a slew rate compensation unit.

The buffer control unit may include a plurality of transistors, for example, first, third, fourth, fifth, and seventh transistors 71, 73, 74, 75, and 77, and an inverter 70. The buffer control unit may further be connected to other switches or transistors. The buffer unit 131D or buffer circuit may include second, fourth, and eighth transistors 72, 74, and 78. The first, second, sixth, seventh, and eighth transistors 71, 72, 76, 77, and 78 may include NMOS transistors, and the third, fourth, and fifth transistors 73, 74, and 75 may include PMOS transistors. At least one of the first to eighth transistors 71, 72, 73, 74, 75, 76, 77, and 78 may further be connected to a PMOS transistor or an NMOS transistor. The sixth and eighth transistors 76 and 78 may perform a current mirror function.

The drain terminal of the first transistor 71 is connected to the source terminal of the seventh transistor 77, the gate terminal and drain terminal of the seventh transistor 77 are connected to each other, and the source terminal of the sixth transistor 66 is connected to the node where the gate terminal and drain terminal of the seventh transistor 77 are connected. The drain terminal of the second transistor 72 is connected to the gate terminal of the output transistor 57, and the node N2 where the drain terminal of the second transistor 72 and the gate terminal of the output transistor 57 are connected is connected to the source terminal of the eighth transistor 78.

The gate terminal of the sixth transistor 76 and the gate terminal of the eighth transistor 78 are connected to one terminal of the capacitor C1 and the drain terminal of the fourth transistor 74 at the first node ND7. The first node ND7 is the input terminal of the buffer unit 131D.

The gate terminal of the third transistor 73 is connected to the output terminal of the inverter 70, the source terminal is connected to a first current source 101 connected to the power supply voltage VDD, and the drain terminal is connected to a first node ND7 to which one terminal of the capacitor C1 is connected.

The gate terminal of the fourth transistor 74 is connected to a control signal GC, the drain terminal is connected to the first node ND7 and to the first node ND7 to which one terminal of the capacitor C1 is connected, and the source terminal is connected to a second current source 102 connected to the power supply voltage VDD.

The gate terminal of the fifth transistor 75 is connected to a control signal GC, the drain terminal is connected to the drain terminal of the eighth transistor 78, and the source terminal is connected to a power supply voltage VDD.

The gate terminals of the first, second, fourth, and fifth transistors 71, 72, 74, and 75 are simultaneously applied with the control signal GC, and the gate terminal of the third transistor 73 is connected with the control signal GC through an inverter 70. The source terminals of the first and second transistors 71 and 72 and the output transistor 79 are connected to a low voltage or a ground terminal GND.

The connection node N2 connecting the source terminal of the eighth transistor 78 and the drain terminal of the second transistor 72 may be connected to the gate terminal of the output transistor 77. A parasitic capacitance Cp exists between the gate terminal and the drain terminal of the output transistor 77. The capacity of this parasitic capacitance Cp may not have the same value and may vary depending on the manufacturing process of each transistor, changes in operating voltage, operating temperature, etc.

One terminal of the capacitor C1 is connected to the first node ND7 to which the drain terminal of the sixth transistor 76 is connected, and the capacitor C1 may be charged with a first current I1 through a second current source 102 and discharged by the operation of the output transistor 79. The other terminal of the capacitor C1, which is the output node ND0, may be connected to the other terminal of the inductor L1 and the drain terminal of the output transistor 79. The drain terminal of the output transistor 79 outputs a driving voltage Vsw through the output node ND0.

The first, second, fourth, and fifth transistors 71, 72, 74, and 75 may be operated simultaneously by the control signal GC. For example, the first, second, and third transistors 71, 72, and 73 are turned on by a high level of the control signal GC, the fourth and fifth transistors 74 and 75 are turned off, and the output transistor 77 is turned off. At this time, the fourth current I4 flows through the first current source 101 and the third transistor 73 to the path of the sixth, seventh, and first transistors 76, 77, and 71, and the driving voltage Vsw is output at a high level.

The first, second, and third transistors 71, 72, and 73 are turned off by a low level of the control signal GC, the fourth and fifth transistors 74 and 75) are turned on, and the eighth transistor 78 and the output transistor 79 are turned on. At this time, the first current I1 flows to the capacitor C1 through the second current source 102 and the fourth transistor 74 and is charged, and the third current I3 is input to the gate terminal of the output transistor 79 through the eighth transistor 78 and flows to the parasitic capacitance Cp. The driving voltage Vsw is output at a low level to the output node ND0 of the drain terminal of the output transistor 79.

The second current I2 flowing to the output node ND0 through the inductor L1 connected to the external power source Vin flows along a path set according to the turn-on or turn-off of the output transistor 79. For example, when the output transistor 79 is turned on, the current ID flows from the drain terminal to the source terminal through the output transistor 79.

The current flowing from the first current source 101 to the third transistor 73, the sixth transistor 76, the seventh transistor 77, and the first transistor 71 is a fourth current I4, the current flowing from the second current source 102 to the capacitor C1 through the fourth transistor 74 is a first current I1, the current flowing through the inductor L1 connected to the external power source Vin and the drain terminal of the output transistor 79 is a second current I2, and the current flowing to the parasitic capacitance Cp of the output transistor 79 may be defined as a third current I3.

As shown in FIGS. 14 and 15, when the control signal GC transitions from a high level to a low level (at time t1), the first voltage V1 at the first node ND7, which is one terminal of the capacitor C1, receives the first current I1 from the gate-source voltage VGS2 of the seventh transistor 77 until the drain current of the seventh transistor 77 becomes equal to the fourth current I4 and rises with a slope (I1/C1) by the capacitor C1. Thereafter, the gate voltage VG of the output transistor 77 rises to the same level as the first voltage V1. That is, the first voltage V1 receives the first current I1 from the gate-source voltage VGS2 of the seventh transistor 77 during the transition of the control signal GC and rises with a voltage slope (I1/C1) according to the capacitance value of the capacitor C1.

Thereafter, when the current ID of the driving voltage Vsw becomes equal to the second current I2, the gate voltage VG of the output transistor 79 becomes the gate-source voltage VGS1 of the output transistor 79, and the driving voltage Vsw begins to fall (time point t2).

The voltage VG at the gate terminal of the output transistor 79 becomes the gate-source voltage VGS1 of the output transistor 79 when the current ID at the drain terminal of the output transistor 79 becomes equal to the sum of the first, second, and third currents I1, I2, and I3 (at time t2, ID=I1+I2+I3), and the gate voltage becomes the Miller plateau voltage of the output transistor 79 and may be reduced to the slope VS1 of the driving voltage Vsw output from the output transistor 79, i.e., I1/C1. As the gate-source voltage VGS1 of the output transistor 79 approaches the Miller plateau voltage of the output transistor 79, the capacitor C1 begins to discharge current. The above slope VS1 changes to the value of I1/C1 from the second time point t2 to the third time point t3 by the capacitor C1, and the difference from the design reference voltage Ref may be reduced.

Accordingly, the voltage VG at the gate terminal of the output transistor 79 rises from the gate-source voltage VGS2 of the seventh transistor 77 and is delayed until the start of the falling transition of the driving voltage Vsw. Accordingly, the voltage VG at the gate terminal of the output transistor 79 rises from the initial level of the gate-source voltage of the output transistor 79 by the gate-source voltage VGS2 of the seventh transistor 77 and is delayed until the falling transition of the driving voltage, and may be reduced compared to the delay of FIG. 2.

The capacitor C1 has a small deviation, that is, a small difference in capacity during manufacturing, so that the slope of the driving voltage of the output transistor may be output consistently. In addition, the deviation between the driving voltages Vsw output from the output transistors of each of the plurality of gate drivers may also be reduced. That is, the present disclosure may reduce the slope deviation of the driving voltage by adding a Miller capacitor C1 between the input terminal and the output terminal of the buffer circuit. In addition, the slope deviation between the gate voltages VG and the slope deviation between the driving voltages Vsw between the transistors in the plurality of gate driver circuits may be reduced. The slope VS1 is controlled by the gate-source voltage VGS2 of the seventh transistor 77 at the initial level of the output transistor 79 and changes to the value of I1/C1 from the second time point t2 to the third time point t3 by the capacitor C1, thereby reducing the difference from the design reference voltage Ref.

Table 7 shows the starting point, the slope delay during the falling time, and the slope of the driving voltage of the output transistor 79 according to the seventh aspect of the present disclosure. Here, VGS1@ID=I2 represents the drain-gate voltage when the drain current ID and the second current I2 are equal, and VGS1@ID=I1+I2+I3 represents the drain-gate voltage when the drain current ID is equal to the sum of the first, second, and third currents I1, I2, and I3.

TABLE 7

| | |
|---|---|
| Delay in the falling point | {((VGS1@ID = I2) − |
| of the driving voltage (Vsw) | (VGS2@ID = D1)) × C1}/I1 |
| Delay in the target slope | {(VGS1@ID = I1 + |
| of the driving voltage | I2 + I3) × C1}/I1 |
| dVsw/dt | I1/C1 |

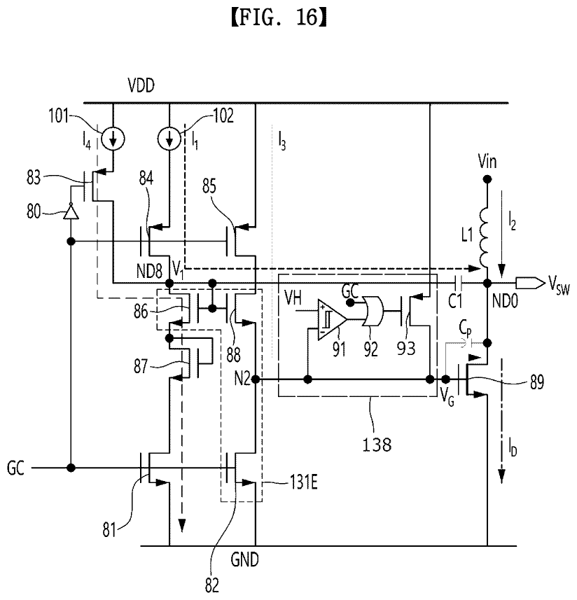

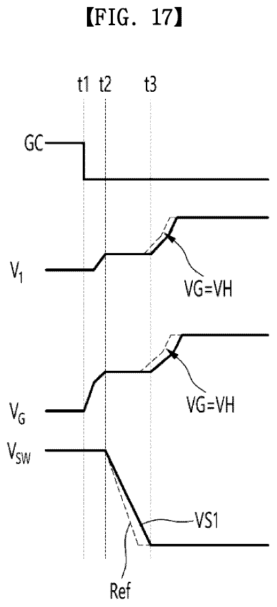

FIG. 16 is a circuit diagram of a circuit for controlling a slew rate according to an eighth aspect of the present disclosure, or a circuit configuration of a gate driver including the same, and FIG. 17 is a waveform diagram of each part of FIG. 16. The eighth aspect is a modified example of the seven aspect, and the same configuration as the seventh aspect will be described in the seven aspect.

Referring to FIG. 16, the gate driver may include a buffer control unit including a plurality of transistors 81, 83, 84, and 85 and an inverter 80, a buffer unit 131E or a buffer circuit, a slope compensation circuit (138:90, 91, and 92), an output transistor 89 as an output switch unit, and a capacitor C1 as a slew rate compensation unit.

The buffer control unit may include a plurality of transistors, for example, first, third, fourth, and fifth transistors 71, 73, 74, and 75 and an inverter 80. The buffer control unit may further include other switches or transistors. The buffer unit 131E or buffer circuit may include second, sixth, and eighth transistors 72, 76, and 78. The slope compensation circuit 138 may include a tenth transistor 93, a comparator 91, and an OR circuit 92.

The first, second, sixth, seventh, and eighth transistors 81, 82, 86, 87, and 88 may include NMOS transistors, and the third, fourth, fifth, and tenth transistors 83, 84, 85, and 93 may include PMOS transistors. The output transistor 89 may be a ninth transistor and may include an NMOS transistor. At least one of the first to eighth transistors 81-88 may further be connected to a PMOS transistor or an NMOS transistor. The sixth and eighth transistors 86 and 88 may function as current mirrors.

The drain terminal of the first transistor 81 is connected to the source terminal of the seventh transistor 87, the gate terminal and drain terminal of the seventh transistor 87 are connected to each other, and the source terminal of the sixth transistor 86 is connected to the node to which the gate terminal and drain terminal of the seventh transistor 87 are connected. The drain terminal of the second transistor 82 is connected to the gate terminal of the output transistor 89, and the node N2 where the drain terminal of the second transistor 82 and the gate terminal of the output transistor 89 are connected is connected to the source terminal of the eighth transistor 88.

The gate terminal of the sixth transistor 86 and the gate terminal of the eighth transistor 88 are connected to one terminal of the capacitor C1 and the drain terminal of the fourth transistor 84 at the first node ND8. The first node ND8 is the input terminal of the buffer unit 131E.

The gate terminal of the third transistor 83 is connected to the output terminal of the inverter 80, the source terminal is connected to a first current source 101 connected to the power supply voltage VDD, and the drain terminal is connected to the first node ND8 to which one terminal of the capacitor C1 is connected. The gate terminal of the fourth transistor 84 is connected to a control signal GC, the drain terminal is connected to a first node ND8, and is connected to the first node ND8 to which one terminal of the capacitor C1 is connected, and the source terminal is connected to a second current source 102 connected to a power supply voltage VDD. The gate terminal of the fifth transistor 85 is connected to a control signal GC, the drain terminal is connected to the drain terminal of the eighth transistor 88, and the source terminal is connected to the power supply voltage VDD.

The comparator 91 has a negative terminal (−) connected to a node N2 connected to the gate terminal of the output transistor 89, and a high signal VH is supplied to a positive terminal (+). The OR circuit 92 receives the output terminal of the comparator 91 and the control signal GC and outputs a high or low level according to the result of the logical sum operation. The gate terminal of the tenth transistor 93 is connected to the output terminal of the OR circuit 92, the drain terminal is connected to the gate terminal of the output transistor 89, and the source terminal is connected to the power voltage VDD.

The control signal GC is simultaneously applied to the gate terminals of the first, second, fourth, and fifth transistors 81, 82, 84, and 85 and the OR circuit 92, and the control signal GC is applied to the gate terminal of the third transistor 83 through the inverter 80. The source terminals of the first and second transistors 81 and 82 and the output transistor 89 are connected to a low voltage or a ground terminal GND.

The connection node N2, where the source terminal of the eighth transistor 88 and the drain terminal of the second transistor 82 are connected, may be connected to the gate terminal of the output transistor 89. A parasitic capacitance Cp exists between the gate terminal and the drain terminal of the output transistor 89. The capacity of this parasitic capacitance Cp may not have the same value and may vary depending on changes in the manufacturing process, operating voltage, and operating temperature of each transistor. Accordingly, a problem may arise in which the driving voltage Vsw output from the output transistor 89 varies depending on the manufacturing characteristics.

One terminal of the capacitor C1 is connected to the first node ND8 to which the drain terminal of the sixth transistor 86 is connected. The capacitor C1 may be charged with a first current I1 through the second current source 102 and discharged by the operation of the output transistor 89. The other terminal of the capacitor C1, the output node ND0, may be connected to the other terminal of the inductor L1 and the drain terminal of the output transistor 89. The drain terminal of the output transistor 89 outputs a driving voltage Vsw through the output node ND0.

The first, second, fourth, and fifth transistors 81, 82, 84, and 85 may be operated simultaneously by the control signal GC. For example, the first, second, and third transistors 81, 82, and 83 are turned on by the high level of the control signal GC, the fourth and fifth transistors 84 and 85 are turned off, and the output transistor 89 is turned off. At this time, the fourth current I4 flows through the first current source 101 and the third transistor 83 to the path of the sixth, seventh, and first transistors 86, 87, and 81, and the driving voltage Vsw is output at a high level.

The first, second, and third transistors 81, 82, and 83 are turned off by the low level of the control signal GC, the fourth and fifth transistors 84 and 85 are turned on, and the eighth transistor 88 and the output transistor 89 are turned on. At this time, the first current I1 flows to the capacitor C1 through the second current source 102 and the fourth transistor 84 and is charged, and the third current I3 is input to the gate terminal of the output transistor 89 through the eighth transistor 88 and flows to the parasitic capacitance Cp. The driving voltage Vsw is output at a low level to the output node ND0 of the drain terminal of the output transistor 89.

The second current I2 flowing to the output node ND0 through the inductor L1 connected to the external power source Vin flows along a path set according to the turn-on or turn-off of the output transistor 89. For example, when the output transistor 89 is turned on, the current ID flows from the drain terminal to the source terminal through the output transistor 89.

The current flowing from the first current source 101 to the third transistor 83, the sixth transistor 86, the seventh transistor 87, and the first transistor 81 is the fourth current I4, the current flowing from the second current source 102 to the capacitor C1 through the fourth transistor 84 is the first current I1, the current flowing through the inductor L1 connected to the external power source Vin and the drain terminal of the output transistor 89 is the second current I2, and the current flowing to the parasitic capacitance Cp of the output transistor 89 may be defined as the third current I3.

The comparator 91 receives a high signal VH and a gate voltage VG of an output transistor 89, compares the levels of the two input voltages, and outputs a high or low level signal. For example, the comparator outputs a high level when the signal VH of the positive terminal (+) is greater than the input voltage VG of the negative terminal (−) connected to the gate terminal of the output transistor 89, and conversely, when the input voltage of the positive terminal is less than the input voltage of the negative terminal, the comparator outputs a low level.

The logical combination circuit 92 receives the output level of the comparator 91 and the control signal CG, and outputs a high signal when the logical combination of the two signals is ‘1’, and outputs a low signal when it is ‘0’. The tenth transistor 93 has a source terminal connected to the power supply voltage VDD, a gate terminal connected to the output terminal of the OR circuit 92, and a drain terminal connected to the gate terminal of the output transistor 89. The tenth transistor 93 is turned on when the output of the OR circuit 92 is at a low level, and is turned off when the output is at a high level.

The tenth transistor 93 is turned on when the output of the OR circuit 92 is at a low level (i.e., when both inputs of the OR circuit 92 are low signals), thereby increasing the gate voltage VG. At this time, when the two inputs VG and VH of the comparator 91 satisfy VG>VH, the 10th transistor 93 is turned on to increase the slope VS1, thereby reducing the deviation from the slope Ref of the reference voltage.

As shown in FIGS. 16 and 17, when the control signal GC transitions from a high level to a low level (time point t1), the first voltage V1 at the first node ND8, which is one terminal of the capacitor C1, receives the first current I1 from the gate-source voltage VGS2 of the seventh transistor 87 until the drain current of the seventh transistor 87 becomes equal to the fourth current I4, and increases to the slope (I1/C1) by the capacitor C1. After this, the gate voltage VG of the output transistor 89 rises to the same level as the first voltage V1. That is, the first voltage V1 receives the first current I1 from the gate-source voltage VGS2 of the seventh transistor 87 during the transition of the control signal GC and rises with a voltage slope (I1/C1) according to the capacitance value of the capacitor C1.

Thereafter, when the current ID of the driving voltage Vsw becomes equal to the second current I2, the gate voltage VG of the output transistor 89 becomes the gate-source voltage VGS1 of the output transistor 89, and the driving voltage Vsw begins to fall (time point t2).

The voltage VG of the gate terminal of the output transistor 89 becomes the gate-source voltage VGS1 of the output transistor 89 when the current ID of the drain terminal of the output transistor 89 becomes equal to the sum of the first, second, and third currents I1, I2, and I3 (ID=I1+I2+I3) (time point t2), and the gate voltage becomes the Miller plateau voltage of the output transistor 89 and may be reduced to the slope VS1 of the driving voltage Vsw output from the output transistor 89, i.e., I1/C1. That is, as the gate-source voltage VGS1 of the output transistor 89 approaches the Miller plateau voltage of the output transistor 89, the capacitor C1 begins to discharge current. The above slope VS1 changes to the value of I1/C1 from the second time point t2 to the third time point t3 by the capacitor C1, and at this time, when the two inputs VG and VH of the comparator 91 are VG>VH, the turn-on of the tenth transistor 93 may cause the slope VS1 to rise more rapidly, thereby reducing the deviation from the slope Ref of the reference voltage.

Accordingly, the voltage VG of the gate terminal of the output transistor 89 rises from the gate-source voltage VGS2 of the seventh transistor 87 and is delayed until the start of the falling transition of the driving voltage Vsw. Accordingly, the voltage VG at the gate terminal of the output transistor 89 is delayed until the gate-source voltage VGS2 of the seventh transistor 87 rises and the driving voltage falls, and may be reduced compared to the delay of FIG. 2. The capacitor C1 has a small deviation, that is, a difference in capacity during manufacturing, so that the slope of the driving voltage of the output transistor may be output consistently. In addition, the deviation between the driving voltages Vsw output from each of the output transistors of the plurality of gate drivers may also be reduced. That is, the present disclosure may reduce the slope deviation of the driving voltage by further adding a Miller capacitor C1 between the input terminal and the output terminal of the buffer circuit. In addition, the slope deviation between the gate voltages VG and the slope deviation between the driving voltages Vsw between the transistors in the plurality of gate driver circuits may be reduced. The above slope VS1 changes to the value of I1/C1 from the second time point t2 to the third time point t3 by the capacitor C1, and may reduce the difference from the design reference voltage Ref.

Table 8 shows the falling time point, the slope delay during the falling time, and the slope of the driving voltage of the output transistor 89 according to the eighth aspect of the present disclosure. Here, VGS1@ID=I2 represents the drain-gate voltage when the drain current ID and the second current I2 are equal, and VGS1@ID=I1+I2+I3 represents the drain-gate voltage when the drain current ID is equal to the sum of the first, second, and third currents I1, I2, and I3.

TABLE 8

| | |
|---|---|
| Delay in the falling point | {((VGS1@ID = I2) − |
| of the driving voltage (Vsw) | (VGS2@ID = D1)) × C1}/I1 |
| Delay in the target slope | {(VGS1@ID = I1 + |
| of the driving voltage | I2 + I3) × C1}/I1 |
| dVsw/dt | I1/C1 |

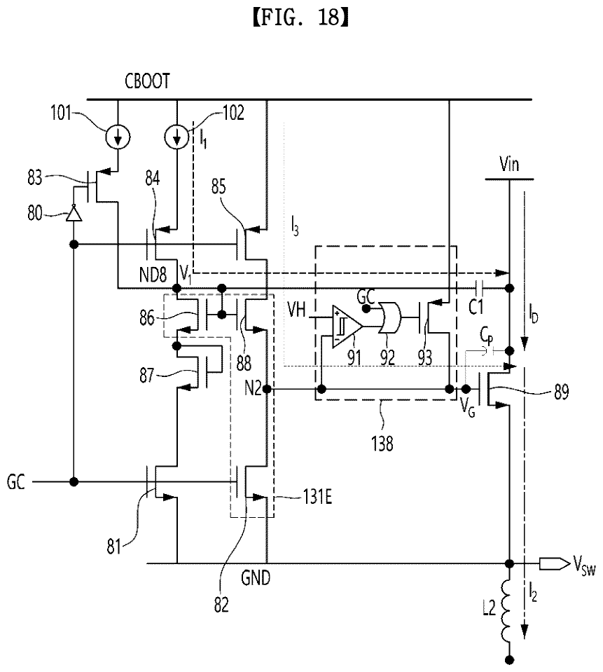

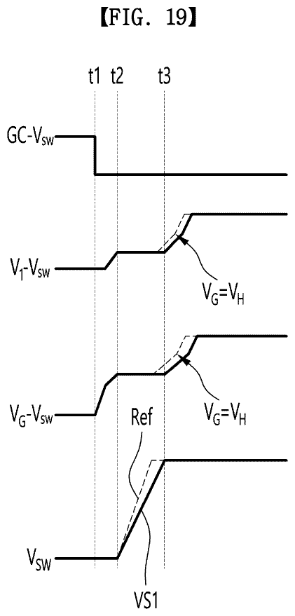

FIG. 18 is a circuit diagram of a circuit for controlling a slew rate according to a ninth aspect of the present disclosure, or a circuit configuration of a gate driver including the same, and FIG. 19 is a waveform diagram of each part of FIG. 18. The ninth aspect is a modified example of the eight aspect, and the same configuration as the eighth aspect will be described in the description of the eight aspect.

Referring to FIG. 18, the gate driver may include a buffer control unit including a plurality of transistors 81, 83, 84, and 85 and an inverter 80, a buffer unit 131E or a buffer circuit, a slope compensation circuit 138, an output transistor 89 as an output switch unit, and a capacitor C1 as a slew rate compensation unit.

The buffer control unit may include a plurality of transistors, for example, first, third, fourth, and fifth transistors 71, 73, 74, and 75 and an inverter 80. The buffer control unit may further include other switches or transistors. The buffer unit 131E or the buffer circuit may include second, sixth, and eighth transistors 72, 76, and 78. The slope compensation circuit 138 may include a tenth transistor 93, a comparator 91, and an OR circuit 92.

The first, second, sixth, seventh, and eighth transistors 81, 82, 86, 87, and 88 may include NMOS transistors, and the third, fourth, fifth, and tenth transistors 83, 84, 85, and 93 may include PMOS transistors. The output transistor 89 may be a ninth transistor and may include an NMOS transistor. At least one of the first to eighth transistors 81-88 may further be connected to a PMOS transistor or an NMOS transistor. The sixth and eighth transistors 86 and 88 may function as current mirrors.

The connection between the first to eighth transistors 81-88 and the output transistor 89 will be described with reference to FIG. 18. The control signal GC line is connected to the inverter 80, the gate terminals of the first and second transistors 81 and 82, and the gate terminals of the fourth and fifth transistors 84 and 85. In addition, the control signal CG line is connected to one terminal of a logical OR circuit 92. The source terminal of the output transistor 89 and the driving voltage Vsw terminal are connected to the source terminal of the first and second transistors 81 and 82.

The drain terminal of the second transistor (82) is connected to the gate terminal of the output transistor 89 at the node N2, and the source terminal of the eighth transistor 88 is connected to the node N2. The gate terminal of the sixth transistor 86 and the gate terminal of the eighth transistor 88 are connected to one terminal of the capacitor C1 and the drain terminal of the fourth transistor 84 at the first node ND8. The first node ND8 is the input terminal of the buffer unit 131E.

The power supply voltage CBOOT terminal is connected to the source terminal of the third transistor 83 through the first current source 101, to the source terminal of the fourth transistor 84 through the second current source 102, and to the source terminal of the fifth transistor 85 and the source terminal of the tenth transistor 93. The power supply voltage CBOOT is a voltage supplied to a bootstrap circuit and applies a sufficient gate drive voltage to the high-side MOSFET.

The drain terminal of the fourth transistor 84 and one terminal of the capacitor C1 are connected to the first node ND8. The other terminal of the capacitor C1 is connected to an external power supply Vin and the drain terminal of the output transistor 89.

The gate terminal of the output transistor 89 is connected to the drain terminal of the tenth transistor 93 of the slope compensation circuit 138 and node N2. The source terminal of the output transistor 89 is connected to a driving voltage Vsw terminal, and one terminal of the inductor L2 is connected to the driving voltage Vsw terminal.

Currents flow along a set path depending on whether the output transistor 89 is turned on or off. For example, when the output transistor 89 is turned on, a current ID flows to the drain terminal through an external power source Vin and the output transistor 89, and a second current I2 flows to the inductor L2 through the source terminal.

The current flowing through the parasitic capacitance Cp of the output transistor 89 may be defined as the third current I3. A parasitic capacitance Cp exists between the gate terminal and the drain terminal of the output transistor 89. The capacity of this parasitic capacitance Cp may not have the same value and may vary depending on changes in the manufacturing process, operating voltage, and operating temperature of each transistor. Accordingly, a problem may arise in which the driving voltage Vsw of the output transistor 89 varies depending on the manufacturing characteristics.

The first, second, fourth, and fifth transistors 81, 82, 84, and 85 may be operated simultaneously by the control signal GC. For example, the first, second, and third transistors 81, 82, and 83 are turned on by the high level of the control signal GC, the fourth and fifth transistors 84 and 85 are turned off, and the output transistor 89 is turned off. At this time, the current passing through the first current source 101 and the third transistor 83 flows to the path of the sixth, seventh, and first transistors 86, 87, and 81, and the driving voltage Vsw is output at a low level.

The first, second, and third transistors 81, 82, and 83 are turned off by the low level of the control signal GC, the fourth and fifth transistors 84 and 85 are turned on, and the eighth transistor 88 and the output transistor 89 are turned on. At this time, the first current I1 flows to the capacitor C1 through the second current source 102 and the fourth transistor 84 and is charged, and the third current I3 is input to the gate terminal of the output transistor 89 through the eighth transistor 88 and flows to the parasitic capacitance Cp. A low level is output to the output node ND0 of the source terminal of the output transistor 89, and the driving voltage Vsw is output at a high level.

The comparator 91 receives a high signal VH and the gate voltage VG of the output transistor 89, compares the levels of the two input voltages, and outputs a high or low level signal. For example, the comparator outputs a high level when the input voltage VH of the positive terminal (+) is greater than the input voltage VG of the negative terminal (−) connected to the gate terminal of the output transistor 89, and conversely, when the input voltage of the positive terminal is less than the input voltage of the negative terminal, the comparator outputs a low level.

The OR circuit 92 receives the output level of the comparator 91 and the control signal CG, and outputs a high signal when the logical sum of the two signals is ‘1’, and outputs a low signal when it is ‘0’. The tenth transistor 93 has a source terminal connected to the power supply voltage VDD, a gate terminal connected to the output terminal of the OR circuit 92, and a drain terminal connected to the gate terminal of the output transistor 89. The above tenth transistor 93 is turned on when the output of the OR circuit 92 is at a low level, and is turned off when the output is at a high level.

The above tenth transistor 93 is turned on when the output of the OR circuit 92 is at a low level (i.e., when both inputs of the OR circuit 92 are low signals), thereby increasing the gate voltage VG. At this time, the tenth transistor 93 is turned on when the two inputs VG and VH of the comparator 91 satisfy VG>VH, thereby increasing the slope VS1, thereby reducing the deviation from the slope Ref of the reference voltage.

As shown in FIG. 19, since the driving voltage Vsw is connected to the source terminal of the output transistor 89, the level of the control signal GC is a voltage obtained by subtracting the voltage level of the driving voltage Vsw from the voltage level of the control signal (e.g., ‘GC-Vsw’), the voltage of the first node ND1 is a voltage obtained by subtracting the voltage level of the same voltage Vsw from the voltage V1 (e.g., ‘V1−Vsw’), and the voltage VG of the gate terminal of the output transistor 89 is supplied as a voltage obtained by subtracting the voltage level of the driving voltage Vsw (e.g., ‘VG−Vsw’).

The gate voltage VG of the output transistor 89 rises to the same level as the first voltage V1. That is, the first voltage (‘V1−Vsw’) receives the first current I1 from the gate-source voltage of the seventh transistor 87 during the transition of the control signal GC and increases with a voltage slope (I1/C1) according to the capacitance value of the capacitor C1.

Thereafter, when the current ID becomes equal to the second current I2, the gate voltage VG of the output transistor 89 becomes the gate-source voltage of the output transistor 89, and the increase of the driving voltage Vsw begins (time point t2). The voltage VG of the gate terminal of the output transistor 89 becomes the gate-source voltage of the output transistor 89 when the current ID of the drain terminal of the output transistor 89 becomes equal to the sum of the first and third currents I1 and I3 (‘ID=I1+I3’) (time point t2), and the gate voltage becomes the Miller plateau voltage of the output transistor 89 and may rise to the slope VS1 of the driving voltage Vsw of the output transistor 89, i.e., I1/C1. That is, as the gate-source voltage of the output transistor 89 approaches the Miller plateau voltage of the output transistor 89, the capacitor C1 begins to discharge current. The above slope VS1 changes to the value of I1/C1 from the second time point t2 to the third time point t3 by the capacitor C1, and at this time, when the two inputs VG and VH of the comparator 91 are ‘VG>VH’, the slope VS1 may be lowered more rapidly by turning on the 10th transistor 93, thereby reducing the deviation from the slope Ref of the reference voltage. In the case where the output transistor 89 is a high-side NMOS FET, when the driving voltage Vsw rises, the gate voltage of the output transistor 89 is rapidly raised to the threshold voltage from the initial voltage of the first voltage V1, and the slope of the driving voltage Vsw is controlled through the feedback of the capacitor C1, and when the gate-source voltage VGS of the output transistor 89 becomes sufficiently high, the rising time of the output transistor 89 may be reduced through the tenth transistor 93, which is a PMOS FET.

Therefore, the voltage VG at the gate terminal of the output transistor 89 rises from the gate-source voltage of the seventh transistor 87 and is delayed until the start of the rising transition of the driving voltage Vsw. Accordingly, the voltage VG at the gate terminal of the output transistor 89 may be delayed until the gate-source voltage VGS2 of the seventh transistor 87 rises and the rising transition of the driving voltage begins. The capacitor C1 has a small deviation, that is, a small difference in capacity during manufacturing, so that the slope of the driving voltage of the output transistor may be output consistently. In addition, the deviation between the driving voltages Vsw output from the output transistors of each of the plurality of gate drivers may be reduced. That is, the present disclosure may reduce the slope deviation of the driving voltage by adding a Miller capacitor C1 between the input terminal and the output terminal of the buffer circuit. In addition, the slope deviation between the gate voltages VG and the slope deviation between the driving voltages Vsw between the transistors in the plurality of gate driver circuits may be reduced. The slope VS1 changes to a value of I1/C1 from the second time point t2 to the third time point t3 by the capacitor C1, and the difference from the design reference voltage Ref may be reduced.

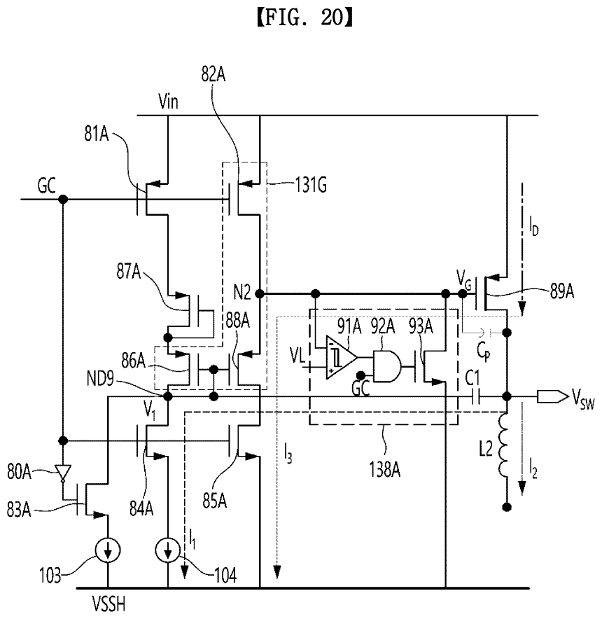

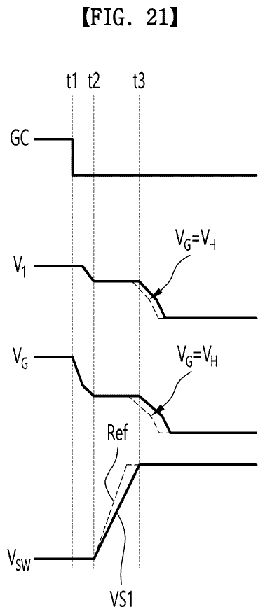

FIG. 20 is a circuit diagram of a circuit for controlling a slew rate according to an eighth aspect of the present disclosure, or a circuit configuration of a gate driver including the same, and FIG. 21 is a waveform diagram of each part of FIG. 20. The tenth aspect is an example in which the NMOS transistor of the ninth aspect is changed to a PMOS transistor, and the PMOS transistor is changed to an NMOS transistor. For the same configuration as the ninth aspect, reference will be made to the description of the ninth aspect.

Referring to FIG. 20, the gate driver may include a buffer control unit including a plurality of transistors 81A, 83A, 84A, and 85A and an inverter 80A, a buffer unit 131G or a buffer circuit, a slope compensation circuit 138A, an output transistor 89A as an output switch unit, and a capacitor C1 as a slew rate compensation unit.

The buffer control unit may include first, third, fourth, and fifth transistors 71A, 73A, 74A, and 75A and an inverter 80A. Other switches or transistors may be further connected to the buffer control unit. The buffer unit 131G or buffer circuit may include second, sixth, and eighth transistors 72A, 76A, and 78A. The slope compensation circuit 138A may include a tenth transistor 93A, a comparator 91A, and an AND circuit 92A.

The first, second, sixth, seventh, and eighth transistors 81A, 82A, 86A, 87A, and 88A may include PMOS transistors, and the third, fourth, fifth, and tenth transistors 83A, 84A, 85A, and 93A may include NMOS transistors. The output transistor 89 may be the ninth transistor and may include a PMOS transistor. A PMOS transistor or an NMOS transistor may be further connected to at least one of the first to eighth transistors 81A-88A. The sixth and eighth transistors 86A and 88A may function as current mirrors.

The drain terminal of the first transistor 81A is connected to the source terminal of the seventh transistor 87A, the gate terminal and drain terminal of the seventh transistor 87A are connected to each other, and the source terminal of the sixth transistor 86A is connected to the node where the gate terminal and drain terminal of the seventh transistor 87A are connected. The drain terminal of the second transistor 82A is connected to the gate terminal of the output transistor 89A, and the node N2 where the drain terminal of the second transistor 82A and the gate terminal of the output transistor 89A are connected is connected to the source terminal of the eighth transistor 88A.

The control signal GC terminal is connected to the gate terminals of the first and second transistors 81A and 82A, the gate terminals of the fourth and fifth transistors 84A and 85A, and the other terminal of the logical product circuit 92A. The source terminals of the first and second transistors 81A and 82A are connected to an external power supply Vin.

The gate terminals of the sixth transistor 86A and the gate terminals of the eighth transistor 88 are connected to one terminal of the capacitor C1 and the drain terminal of the fourth transistor 84 at the first node ND8. The first node ND8 is the input terminal of the buffer unit 131G.

The gate terminal of the third transistor 83A is connected to the output terminal of the inverter 80A, the source terminal is connected to a first current source 103 connected to a low voltage (e.g., ground voltage VSSH), and the drain terminal is connected to a first node ND8 to which one terminal of the capacitor C1 is connected. The drain terminal of the fourth transistor 84A is connected to the first node ND8, and the source terminal is connected to a second current source 104 connected to a low voltage VSSH. The drain terminal of the fifth transistor 85A is connected to the drain terminal of the eighth transistor 88A, and the source terminal is connected to a low voltage VSSH.

The comparator 91A is connected to a node N2 whose negative terminal (−) is connected to the gate terminal of the output transistor 89A, and a low signal VL is supplied to the positive terminal (+). The AND circuit 92A receives the output terminal of the comparator 91A and the control signal GC and outputs a high or low level according to the result of the AND operation. The gate terminal of the tenth transistor 93A is connected to the output terminal of the AND circuit 92A, the drain terminal is connected to the gate terminal of the output transistor 89A, and the source terminal is connected to the low voltage VSSH terminal.

The control signal GC is simultaneously applied to the gate terminals of the first, second, fourth, and fifth transistors 81A, 82A, 84A, and 85A and the AND circuit 92A, and the control signal GC is applied to the gate terminal of the third transistor 83A through the inverter 80A. The source terminals of the first and second transistors 81A and 82A and the output transistor 89A are connected to an external power source Vin.

The node N2, to which the source terminal of the eighth transistor 88A and the drain terminal of the second transistor 82A are connected, may be connected to the gate terminal of the output transistor 89A. A parasitic capacitance Cp exists between the gate terminal and the drain terminal of the output transistor 89A. The capacity of this parasitic capacitance Cp may not have the same value and may vary depending on changes in the manufacturing process, operating voltage, and operating temperature of each transistor. Accordingly, a problem may arise in which the driving voltage Vsw output from the output transistor 89A varies depending on the manufacturing characteristics.

One terminal of the capacitor C1 is connected to the first node ND9 to which the drain terminal of the sixth transistor 86A is connected. The voltage charged in the capacitor C1 may be discharged by the first current I1 through the second current source 102 and charged by the operation of the output transistor 89A. The other terminal of the capacitor C1, which is the output node, may be connected to the other terminal of the inductor L2 and the drain terminal of the output transistor 89A. The drain terminal of the output transistor 89A outputs a driving voltage Vsw through the output node.

The first, second, fourth, and fifth transistors 81A, 82A, 84A, and 85A may be operated simultaneously by the control signal GC. For example, the first, second, and third transistors 81A, 82A, and 83A are turned off by the high level of the control signal GC, the fourth and fifth transistors 84A and 85A are turned on, and the output transistor 89A is turned on. At this time, the driving voltage Vsw is output at a low level.

The first, second, and third transistors 81A, 82A, and 83A are turned on by the low level of the control signal GC, the fourth and fifth transistors 84A and 85A are turned off, and the eighth transistor 88A and the output transistor 89A are turned off. At this time, the first current I1 flows through the drain terminal of the output transistor 89A and the capacitor C1 to the fourth transistor 84A and to the second current source 102, and the third current I3 flows through the gate terminal of the output transistor 89A, the parasitic capacitance Cp, the eighth transistor 88A, and to the fifth transistor 85A. At this time, the driving voltage Vsw is output at a high level to the output node of the drain terminal of the output transistor 89A.

The second current I2 flowing through the inductor L1 is controlled according to the turn-on or turn-off of the output transistor 89A. For example, when the output transistor 89A is turned on, the current ID flows from the source terminal to the drain terminal through the output transistor 89A.

The comparator 91 receives a low signal VL and a gate voltage VG of an output transistor 89A, compares the levels of the two input voltages, and outputs a high or low level signal. For example, the comparator outputs a high level when the signal VL of the positive terminal (−) is greater than the input voltage VG of the negative terminal (−) connected to the gate terminal of the output transistor 89A, and conversely, when the input voltage of the positive terminal is less than the input voltage of the negative terminal, the comparator outputs a low level.

The logical product circuit 92A receives the output level of the comparator 91A and the control signal CG, and outputs a high signal when the logical product of the two signals is ‘1’, and outputs a low signal when it is ‘0’. The tenth transistor 93A has a source terminal connected to a low voltage VSSH, a gate terminal connected to the output terminal of the AND circuit 93A, and a drain terminal connected to the gate terminal of the output transistor 89A. The tenth transistor 93A is turned on when the output of the AND circuit 92A is at a high level, and is turned off when the output is at a low level.

The tenth transistor 93A is turned on when the output of the AND circuit 92A is at a high level (i.e., when both inputs of the AND circuit 92A are high signals), thereby lowering the gate voltage VG. At this time, the tenth transistor 93A is turned on, thereby increasing the slope VS1, thereby reducing the deviation from the slope Ref of the reference voltage.

As shown in FIGS. 20 and 21, when the control signal GC transitions from a high level to a low level (at time t1), the first voltage V1 and the gate voltage VG of the output transistor 89A decrease with a slope (I1/C1) due to the capacitor C1. Thereafter, the gate voltage VG of the output transistor 89A decreases to the same level as the first voltage V1. That is, the first voltage V1 decreases with a voltage slope (I1/C1) due to the capacitance value of the capacitor C1. Thereafter, when the current ID of the driving voltage Vsw becomes equal to the second current I2, the gate voltage VG of the output transistor 89A becomes the gate-drain voltage of the output transistor 89A, and the driving voltage Vsw begins to rise (at time t2).

The voltage VG at the gate terminal of the output transistor 89A becomes a Miller plateau voltage and may be reduced to the slope VS1 of the driving voltage Vsw output from the output transistor 89A, i.e., I1/C1. That is, as the gate-drain voltage of the output transistor 89A approaches the Miller plateau voltage of the output transistor 89A, the capacitor C1 begins to discharge current. The slope VS1 changes to a value of I1/C1 from the second time point t2 to the third time point t3 by the capacitor C1, and at this time, the slope VS1 may be increased more rapidly by the turn-on of the 10th transistor 93A, thereby reducing the deviation from the slope Ref of the reference voltage. Accordingly, the voltage VG at the gate terminal of the output transistor 89A may be delayed until the rising transition of the driving voltage. The capacitor C1 has a small variation, i.e., a small difference in capacity during manufacturing, so that the slope of the driving voltage of the output transistor may be output consistently. Furthermore, the variation between the driving voltages Vsw output from the output transistors of each of the plurality of gate drivers may be reduced. That is, the present disclosure may reduce the slope variation of the driving voltage by adding a Miller capacitor C1 between the input terminal and the output terminal of the buffer circuit. Furthermore, the slope variation between the gate voltages VG and the slope variation between the driving voltages Vsw caused by the transistors within the plurality of gate driver circuits may be reduced.

The gate driver disclosed in the above aspect of the present disclosure may include a plurality of gate drivers connected to the line of the control signal, and the slope variation between the driving voltages may be reduced by connecting the capacitor disclosed above to the drain terminal of each output transistor within the plurality of gate drivers. The above gate driver may be applied to various driver circuits or power management circuits of electronic devices or display devices.

It will be apparent to those skilled in the art that various modifications and variations can be made in the present disclosure without departing from the spirit or scope of the aspects of the present disclosure. Thus, it is intended that the present disclosure covers the modifications and variations of the aspects provided they come within the scope of the appended claims and their equivalents.

What is claimed is:

1. A gate driver for slew rate control, comprising:
a buffer control unit configured to switch and output a power supply voltage in response to a control signal having a high or low level;
a buffer unit configured to delay and output a voltage output from the buffer control unit;
an output switch unit including an output transistor, wherein a gate terminal of the output transistor is connected to an input terminal of the buffer unit, and the output transistor is turned on or off in accordance with a voltage level applied through the buffer unit to output a driving voltage;
a capacitor electrically coupled between the input terminal of the buffer unit and a drain terminal of the output transistor; and
a current source coupled to a power supply voltage terminal and configured to generate a charging current for charging the capacitor,
wherein the capacitor adjusts a slope during a rising or falling transition of a gate voltage of the output transistor, and
the output transistor adjusts a slope during a falling or rising transition of the driving voltage output to the drain terminal according to a capacitance of the capacitor.

2. The gate driver according to claim 1, wherein the buffer control unit includes:
a first switch configured to be selectively turned on or off to connect or disconnect the current source in response to an inverted version of the control signal; and
a second switch configured to be selectively turned on or off to connect or disconnect an output terminal of the first switch in response to the control signal.

3. The gate driver according to claim 2, wherein the buffer unit includes a buffer coupled to a first node between the output terminal of the first switch and an input terminal of the second switch,
one terminal of the capacitor being coupled to the first node and the other terminal of the capacitor being coupled to the drain terminal of the output transistor, and
a gate terminal of the output transistor being coupled to an output terminal of the buffer.

4. The gate driver according to claim 1, wherein the buffer control unit includes:
first to third switches each configured to selectively connect input and output terminals in response to the control signal; and
a first transistor having a drain terminal and a gate terminal coupled to the current source and a source terminal coupled to an input terminal of the first switch.

5. The gate driver according to claim 4, wherein the third switch is coupled to a drain terminal of the first transistor in response to an inverted version of the control signal,
the buffer unit includes a buffer having an input terminal coupled to an input terminal of the second switch and an output terminal of the third switch, and an output terminal coupled to a gate terminal of the output transistor, and
one terminal of the capacitor is coupled to the first node at which the drain terminal of the first transistor and the current source are coupled, and the other terminal of the capacitor is coupled to the drain terminal of the output transistor.

6. The gate driver according to claim 1, wherein the buffer control unit includes:
first to fifth switches each configured to selectively connect input and output terminals in response to the control signal; and
a first transistor having a drain terminal and a gate terminal coupled to output terminals of fourth and fifth switches and a source terminal coupled to an input terminal of the first switch.

7. The gate driver according to claim 6, wherein the third switch is coupled to a drain terminal of the first transistor in response to an inverted version of the control signal,
the fourth switch is configured to selectively connect a first current source coupled to the power supply voltage and the drain terminal of the first transistor in response to the control signal, and
the fifth switch is configured to selectively connect a second current source coupled to the power supply voltage and the drain terminal of the first transistor in response to an inverted version of the control signal.

8. The gate driver according to claim 7, wherein the buffer unit includes a buffer having an input terminal coupled to an input terminal of the second switch and an output terminal of the third switch, and an output terminal coupled to a gate terminal of the output transistor,
one terminal of the capacitor being coupled to the first node at which the drain terminal of the first transistor and output terminals of the fourth and fifth switches connected to the first and second current sources are coupled, and the other terminal of the capacitor being coupled to the drain terminal of the output transistor.

9. The gate driver according to claim 1, wherein the buffer control unit includes a first transistor having a gate terminal coupled to a control signal line,
the buffer unit including:
a second transistor having a gate terminal coupled to the control signal line;
a third transistor having a drain terminal and a gate terminal coupled to the current source and a source terminal coupled to a drain terminal of the first transistor; and
a fourth transistor having a drain terminal coupled to the power supply voltage, a gate terminal coupled to a gate terminal of the third transistor, and a source terminal coupled to the drain terminal of the first transistor,
one terminal of the capacitor being coupled to the first node at which the drain terminal of the first transistor and a source terminal of the third transistor are connected, and the other terminal of the capacitor being coupled to the drain terminal of the output transistor.

10. The gate driver according to claim 1, wherein the buffer control unit includes:
a first transistor having a gate terminal coupled to a control signal line;
a third transistor having a gate terminal coupled to the control signal line and a source terminal coupled to the power supply voltage; and
a fifth transistor having a source terminal coupled to a drain terminal of the first transistor and a drain terminal and a gate terminal coupled to the first node to which the buffer unit is coupled.

11. The gate driver according to claim 10, wherein the buffer unit includes:
a second transistor having a gate terminal coupled to the control signal line and a drain terminal coupled to a gate terminal of the output transistor;
a fourth transistor having a drain terminal and a gate terminal coupled to the current source and a source terminal coupled to the first node; and
a sixth transistor having a gate terminal coupled to the current source, a drain terminal coupled to a drain terminal of the third transistor, and a source terminal coupled to both the drain terminal of the second transistor and the gate terminal of the output transistor,
one terminal of the capacitor being coupled to the first node, and the other terminal of the capacitor being coupled to the drain terminal of the output transistor.

12. The gate driver according to claim 1, wherein the buffer control unit includes:
a first transistor having a gate terminal coupled to a control signal line;
a third transistor having a gate terminal coupled to the control signal line and a source terminal coupled to the power supply voltage; and
a fifth transistor having a source terminal coupled to a drain terminal of the first transistor and a drain terminal and a gate terminal coupled to the buffer unit.

13. The gate driver according to claim 12, wherein the buffer unit includes:
a second transistor having a gate terminal coupled to the control signal line and a drain terminal coupled to a gate terminal of the output transistor;
a fourth transistor having a drain terminal and a gate terminal coupled to the first node to which the current source is coupled and a source terminal coupled to a drain terminal of the fifth transistor; and
a sixth transistor having a source terminal coupled to both the drain terminal of the second transistor and the gate terminal of the output transistor,
one terminal of the capacitor being coupled to the first node at which the drain terminal of the fourth transistor and the current source are coupled, and the other terminal of the capacitor being coupled to the drain terminal of the output transistor.

14. The gate driver according to claim 1, wherein the buffer control unit includes:
a first transistor having a gate terminal coupled to a control signal line;
an inverter configured to invert the control signal;
a third transistor having a source terminal coupled to a first current source coupled to the power supply voltage and a gate terminal coupled to the inverter;
a fourth transistor having a source terminal coupled to a second current source coupled to the power supply voltage and a gate terminal coupled to the control signal line;
a fifth transistor having a source terminal coupled to the power supply voltage and a gate terminal coupled to the control signal line; and
a seventh transistor having a drain terminal and a gate terminal coupled to the buffer unit and a source terminal coupled to a drain terminal of the first transistor.

15. The gate driver according to claim 14, wherein the buffer unit includes:
a second transistor having a gate terminal coupled to the control signal line and a drain terminal coupled to a gate terminal of the output transistor;
a sixth transistor having a drain terminal and a gate terminal coupled to the first node at which drain terminals of the third and fourth transistors are coupled; and
an eighth transistor having a drain terminal coupled to a drain terminal of the fifth transistor, a gate terminal coupled to the first node, and a source terminal coupled to the gate terminal of the output transistor,
one terminal of the capacitor being coupled to the first node at which the drain terminals of the fourth and sixth transistors are coupled, and the other terminal of the capacitor being coupled to the drain terminal of the output transistor.

16. The gate driver according to claim 2, further comprising a slope compensation circuit coupled between the buffer and the output transistor,
the slope compensation circuit including:
a comparator configured to compare a voltage level of the gate terminal of the output transistor coupled to a negative input terminal with a high level of a positive input terminal and to output a comparison result;
a logic OR circuit configured to logically combine the output of the comparator and the control signal; and
a tenth transistor having a gate terminal coupled to an output terminal of the logic OR circuit, a source terminal coupled to the power supply voltage, and a drain terminal coupled to the gate terminal of the output transistor.

17. The gate driver according to claim 2, further comprising an inductor having one terminal to which an external power supply is applied and another terminal coupled to both the drain terminal of the output transistor and the other terminal of the capacitor,
wherein the output transistor includes an NMOS transistor.

18. The gate driver according to claim 2, wherein when the control signal transitions from a high level to a low level, a voltage of a gate terminal of the output transistor rises with a slope of a first current applied through the first node charged by the capacitor, and a driving voltage decreases with a slope of the first current charged in the capacitor.

19. The gate driver according to claim 1, wherein the gate driver includes a plurality of gate drivers coupled to a control signal line.

20. The gate driver according to claim 1, wherein the capacitor has a capacitance greater than a parasitic capacitance between a gate terminal and a drain terminal of the output transistor.
